(19) United States
(12) Patent Application Publication
(10) Pub. No.: US 2024/0297199 A1
(43) Pub. Date: Sep. 5, 2024

(54) SINGLE PHOTON COLOR IMAGE SENSOR

(71) Applicants: THE REGENTS OF THE UNIVERSITY OF CALIFORNIA, Oakland, CA (US); NATIONAL TECHNOLOGY & ENGINEERING SOLUTIONS OF SANDIA, LLC, Albuquerque, NM (US)

(72) Inventors: Francois Leonard, Brentwood, CA (US); Maurice Garcia-Sciveres, Oakland, CA (US); Mi-Young Im, Berkeley, CA (US); Yuan Mei, El Sobrante, CA (US); Andrew Nonaka, Concord, CA (US); Aikaterini Papadopoulou, Oakland, CA (US); Archana Raja, Kensington, CA (US); Grigory Tikhomirov, Berkeley, CA (US)

(73) Assignees: THE REGENTS OF THE UNIVERSITY OF CALIFORNIA, Oakland, CA (US); NATIONAL TECHNOLOGY & ENGINEERING SOLUTIONS OF SANDIA, LLC, Albuquerque, NM (US)

(21) Appl. No.: 18/613,895

(22) Filed: Mar. 22, 2024

Related U.S. Application Data
(63) Continuation of application No. PCT/US2022/046980, filed on Oct. 18, 2022.
(60) Provisional application No. 63/256,894, filed on Oct. 18, 2021.

(51) Int. Cl. H01L 27/146; H01L 31/02; H01L 31/0352; H01L 31/18

(52) U.S. Cl. CPC H01L 27/14652; H01L 27/14683; H01L 31/02005; H01L 31/035227; H01L 31/18; H01L 31/035218

(57) ABSTRACT

A pixelated electronic sensor is disclosed for imaging from infra-red to ultraviolet wavelengths, composed of a CMOS integrated circuit plus layers of nano-materials monolithically integrated via low temperature post-processing. Co-design, simulation, and integration methods for the device are described. Each pixel has color-resolved single photon sensitivity without dark counts and without inefficiency. The device operates at temperatures above 70° Kelvin. Current state of the art imagers that can color-resolve single photons are of bolometric or filter type. Bolometric devices must operate at temperature below 1° Kelvin and are limited to few pixels. Devices that use filters are inefficient as all the photons rejected by a filter are wasted. Single photon imagers that operate at non-cryogenic temperature (like Silicon Photomultipliers) have large dark counts typically measured in MHz/cm². Imaging applications include astronomical telescopes, exoplanet imaging, distant galaxy imaging, microscopic imaging, medical devices, and hyperspectral imaging.

### CROSS-REFERENCE TO RELATED APPLICATIONS

This application claims priority to, and is a 35 U.S.C. § 111 (a) continuation of, PCT international application number PCT/US2022/046980 filed on Oct. 18, 2022, incorporated herein by reference in its entirety, which claims priority to, and the benefit of, U.S. provisional patent application Ser. No. 63/256,894 filed on Oct. 18, 2021, incorporated herein by reference in its entirety. Priority is claimed to each of the foregoing applications.

The above-referenced PCT international application was published as PCT International Publication No. WO 2023/069405 A2 on Apr. 27, 2023, which publication is incorporated herein by reference in its entirety.

### STATEMENT REGARDING FEDERALLY SPONSORED RESEARCH OR DEVELOPMENT

This invention was made with Government support under contracts DE-AC02-05CH11231 and DE-NA-0003525, both awarded by the U.S. Department of Energy. The Government has certain rights in the invention.

### BACKGROUND

### 1. Technical Field

The technology of this disclosure pertains generally to image sensors and more particularly to single photon color image sensors.

### 2. Background Discussion

Current state of the art image sensors that can color-resolve single photons are of a bolometric-type or a filter-type. Bolometric devices operate at temperature below 1° Kelvin and are limited to few pixels. Devices that use filters (e.g., CCD devices with filters to distinguish different colors) are inefficient, as all the photons rejected by a filter are wasted. Single photon image sensors that operate at non-cryogenic temperature (e.g., silicon photomultipliers) have large dark counts, typically measured in MHz/cm².

### BRIEF SUMMARY

One novel aspect of this invention is the capability of measuring more information about each single photon, namely the wavelength, in addition to detecting intensity or counting photons as existing devices can do. This is achieved by exploiting the quantum superposition of multiple nanosensors, which is why they need to be nanoscale devices—in order to fit several devices within one wavelength of the incoming light.

It is existing hyperspectral imagers (which can be bought commercially) that consist of multiple components integrated into a single platform, where they perform the same function as they do separately. For example, a dispersive element like a grating is used to split an image into multiple colors and each color is recorded with a conventional camera. In contrast, the device described here is inherently hyperspectral. It is a single device that captures spectral information naturally, without the need for any dispersive element. This capability (with high quantum efficiency) emerges from combining the elements used within one wavelength of light so that quantum effects become dominant. In fact, if one were to place the nanosensors further apart the performance plummets. The nanosensors DO NOT perform the same function when they are not together.

Further aspects of the technology described herein will be brought out in the following portions of the specification, wherein the detailed description is for the purpose of fully disclosing preferred embodiments of the technology without placing limitations thereon.

### BRIEF DESCRIPTION OF THE DRAWINGS

The technology described herein will be more fully understood by reference to the following drawings which are for illustrative purposes only:

FIG. 1 is a comparison between existing conventional designs for photon detection (which is termed as a decoupled detector), and a fully coupled quantum detector described herein.

FIG. 2 is a diagram of how a nanosensor is used to detect individual photons, where the nanosensor is connected to an individual pixel, which is in turn connected to a full chip.

FIG. 3A through FIG. 3F are a visual representation of a device development path.

FIG. 3A represents the present state of the art using CNTs from published works.

FIG. 3B is a more advanced functionalization of the CNTs.

FIG. 3C is a completely new nanomaterial sensing layer.

FIG. 3D represents one single nanosensor on one single CMOS pixel on the left.

FIG. 3E is a more complex pixel.

FIG. 3F is a many-pixel demonstrator chip and wafer scale.

FIG. 4 is an illustration of the processes that typically occur during photodetection.

FIG. 5A is an illustration of the general architecture for optimal photodetection.

FIG. 5B is an illustration of an example of system that realizes the general architecture.

FIG. 5C is an illustration of the predicted performance of this system when 99% efficiency is required.

FIG. 6A is an illustration of a potential design for a frequency-resolving detector, where several nanoscale devices are within the wavelength of the photon within a single plane.

FIG. 6B is an illustration of a potential design for a frequency-resolving detector, where several nanoscale devices are within the wavelength of the photon within the single plane of FIG. 6A, and three additional planes.

FIG. 7A through FIG. 7D are illustrations of a concept for integration of CNTs on the CMOS ASIC.

FIG. 7A is a layout of a pad as-built by a CMOS foundry.

FIG. 7B is an addition of a thin dielectric layer on a large electrode that will form the carbon nanotube (CNT) gate.

FIG. 7C is an addition of CNTs to gate electrode area.

FIG. 7D is a deposition of Pd electrodes to connect CNTs to integrated circuit (IC) inputs.

FIG. 8 is a diagram of an expected circuit for integrated CNTs.

FIG. 9A and FIG. 9B are illustrations of waveguide structures modeled by ARTEMIS.

FIG. 10A is an attenuation spectrum computed using ARTEMIS for the waveguide structures of FIG. 9A and FIG. 9B where the waveguide is filled with air.

FIG. 10B is an attenuation spectrum computed using ARTEMIS for a magnetically tunable structure.

FIG. 11A is an illustration of the photodetection mechanism.

FIG. 11B is an atomic force microscope (AFM) image of aligned CNTs in a transistor channel.

FIG. 11C is a scanning electron micrograph (SEM) of a device with an individual CNT.

FIG. 11D is a graphical example of photo-response to a light pulse.

FIG. 12A is a SEM image of individual nanowires between electrodes.

FIG. 12B is an illustrated schematic of a scanning photocurrent approach illustrated for a 2D material.

FIG. 12C is a single photon counting module (SPCM) map for the nanowire of FIG. 12A.

FIG. 12D is a plotted simulation of discrete charge effects on photo-response behavior.

FIG. 13A is a schematic illustration of the process of synthesis and characterization of lithographically patterned transition metal dichalcogenide (TMD) WS₂ structures grown using the Lateral Conversion (LC) method, with the device shown first.

FIG. 13B shows optical microscope images of lithographically patterned structures converted for different amounts of time, demonstrating the ability to produce arbitrary shapes and control the LC extent.

FIG. 13C shows transmission electron micrograph (TEM) cross-section images and plot showing the number of WS₂ layers as a function of WOₓ thickness with thicknesses of 2.4, 3.6, 4.8, 7.2, and 9.6 nm and their corresponding graphical data fits.

FIG. 13D, FIG. 13E, and FIG. 13F show optical images (top) and corresponding Raman spectrum (bottom) of MoS₂, MoSe₂, and WSe₂ grown by lateral conversion for varying amounts of lateral growth.

FIG. 14A is an optical microscope image, and corresponding cross-sectional high-resolution transmission electron microscopy (HRTEM) image of a WS₂/SiO₂ multilayer structure.

FIG. 14B is a schematic diagram of the effect of a patterned transition metal dichalcogenide (TMD) interface on its band structure.

FIG. 14C is an optical microscope image overlaid with scanning confocal Raman spectroscopy indicating the composition.

FIG. 15A is a depiction of quantum dots functionalizing encapsulated TMD surface and exposed edges.

FIG. 15B shows a monolayer MoS₂ and graphene device where a graph of absorption is overlaid with visible quantum dot emission.

FIG. 15C is a graph of the decay rate of quantum dots enhanced by an order of magnitude due to energy transfer on MoS₂ compared to that on insulating SiO₂.

FIG. 16A is a single pixel with extensions that enable alignment to lithographically defined patterns.

FIG. 16B is a depiction of a possible single pixel layout with six CNT channels functionalized with quantum dots that can be tuned to different wavelengths of light.

FIG. 17A through FIG. 17E show a method of self-alignment of nanosensors onto a lithographically patterned CMOS device.

FIG. 17A shows the initial photolithography of an asymmetric patch.

FIG. 17B shows a plasma etch.

FIG. 17C shows photoresist stripping.

FIG. 17D shows the result of photoresist stripping, where a hydrophobic and hydrophilic region have been created.

FIG. 17E shows the top and bottom DNA array alignment.

FIG. 17F shows metal contact deposition.

### DETAILED DESCRIPTION

### 1. Introduction

As traditional CMOS scaling offers diminishing gains in performance, alternative approaches, such as codesign and heterogeneous integration of low-dimensional (0D, 1D and 2D) materials, present new opportunities. This application shows the development of scalable integration of photon nanosensors on a CMOS platform.

Here, the focus is on carbon nanotube (CNT) and 2D materials such as transition metal dichalcogenides (TMDs) hybridized with 1D and 0D materials (respectively molecules and quantum dots).

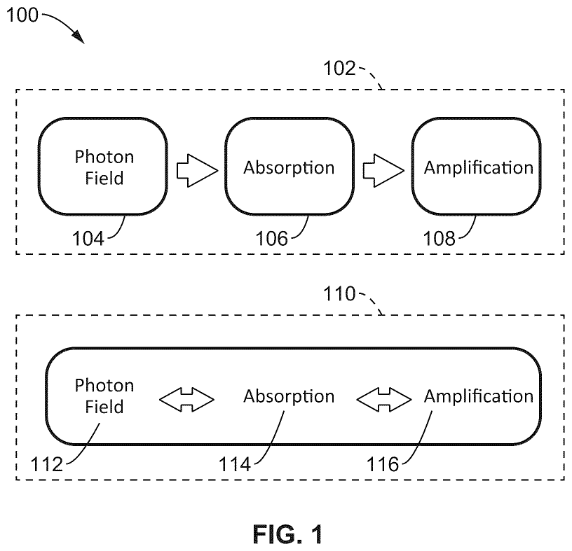

Refer now to FIG. 1, which is a comparison 100 between existing conventional designs 102 for photon detection (which is termed as a decoupled detector), where a photon field 104 undergoes absorption 104 followed by amplification 108, and a fully coupled quantum detector 110 described herein, wherein a photon field 112 undergoes 114 and amplification 116, but does so as an integrated unit 110.

Breakthroughs in photon imaging devices have a broad impact on science across the U.S. Department of Energy (DOE). An ultimate photon imager that precisely maps intensity and spectrum down to single photon sensitivity would be transformative for cosmology, biological imaging, and quantum information science, and would open up a new measurement modality not available today. Scientific CCDs (Charged Coupled Devices) represent the state of the art in cosmological imaging, but they only measure light intensity and not spectrum. Limited spectral information is obtained by taking images with different bandpass filters, but these reject light outside the bandpass, and so necessarily waste photons. Even then, filters only provide coarse information about the spectrum.

Spectrometers are used to obtain precision spectral information without wasting photons, by dispersing light (using a diffraction grating) to different locations of a CCD. Instrumenting every pixel of a telescope's focal plane with its own spectrometer is not practical. For example, the Vera Rubin Observatory camera (an imaging instrument) has 3 Gpixels. Because in any given image only a small fraction of the pixels contain objects of interest, the next best thing to a spectrometer in every pixel is a spectrometer on every object of interest, which is in a different place for each image. So, one must move around the spectrometers from image to image. This is what is done in the Dark Energy Spectroscopic Instrument (DESI) instrument using thousands of fiber positioning robots. This instrument takes spectra, but not images. Thus, two instruments are needed, one to map the sky and another to record spectra. A more capable device than scientific CCDs would record both intensity and spectrum in every pixel, and fully utilize every photon. Furthermore, it would enable infrared astronomy from the ground, which is currently not possible due to strong emission lines from the atmosphere. While there is research to develop filters to suppress only the atmospheric lines, an imaging device with precision spectral information would not require such filters. Spectrally resolved imaging sensors with low dark counts would also be of great use for high resolution biological imaging, potentially enabling ultrafast imaging important for observing fast biological processes in real time.

Dark counts, in this context, are responding pixels of an imaging device (herein referred to as an “imager”) in the absence of any light. For example, in a CCD these can be caused by leakage currents.

Single photon sensitivity is commonly achieved with a variety of sensors in different applications. However, the combination of single photon sensitivity with low dark counts and fast response does not exist in an imager. Avalanche devices, such as SiPMs (Silicon Photo-Multipliers), are both fast and can be single photon sensitive, but have large dark count rates. CCDs have achieved single electron (and therefore single photon) sensitivity, but at very low speeds and must be cooled to cryogenic temperature to suppress dark counts. Intensified devices, for example with micro-channel plates or the new Large Area Picosecond Photodetector (LAPPD) technology, are very high speed and can achieve lower dark counts than SiPMs (but still significant), but have limited position resolution given by their discrete pore pattern. Superconducting Nanowire Single Photon Detectors (SNSPDs) do achieve single photon sensitivity with low dark counts and fast response, but operate near 80° K temperature and require compromises to scale to multi-pixel imagers. None of these devices provide spectroscopic wavelength information about the photons detected.

Development of imaging devices with spectral resolution in every pixel has so far focused on superconducting technology. A 20 kpixel device built with Kinetic Inductance Detectors (KIDs) has already been deployed on the Subaru Telescope for exo-planet imaging, with a spectral resolution of λ/Δλ=5-7 in every pixel (for comparison one dispersive spectrograph has λ/Δλ>2000). Transition Edge Sensors (TES) devices have also shown promise and are being developed for biological imaging applications. They achieve higher spectral resolution than KIDs, but these are difficult to scale to more than a few pixels. Both types of superconducting devices must operate at sub-Kelvin temperature, have slow pixel response times (μs scale), have pixel count limited by readout, which requires cryogenic feed-lines (one unit uses 10 feed lines), and, being micro-calorimeters, are sensitive to any source of energy and must be extremely well shielded and isolated to suppress backgrounds. This disclosure aims to demonstrate a new type of spectral imager that operates at more practical temperatures (up to room temperature), has single photon sensitivity with fast pixel response time (ps scale) and low dark counts, and can be scaled to megapixel devices.

Prior results show that low dimensional materials have great promise as photon detectors towards the above goals, and have achieved few-photon sensitivity at room temperature with functionalized CNTs in stand-alone test structures. However, to produce practical devices, nanosensors must be integrated on CMOS platforms at scale. To that end, this disclosure will expand the theoretical frame work to include the signal processing in the CMOS platform and the TMD materials for which we have developed wafer scale fabrication methods. TMDs have been promising candidate materials for photon sensing applications together with potential for CMOS compatibility via lift-off and transfer techniques. In particular, hybrid TMD/TMD or TMD/quantum dot detectors show high gain, high photosensitivity and low dark currents, with results obtained for visible or NIR light. While the CMOS integration development can be fully demonstrated in the visible range alone, this disclosure investigates different material choices that can provide UV or IR photon sensitivity, which many applications require.

The new type of photon imaging sensor disclosed here will develop tightly integrated nano-materials directly on Application Specific Integrated Circuits (ASICs). This will increase the level of integration beyond the paradigm of back-end hybridization, where a passive sensor is coupled to an ASIC via packaging or 3D integration, as the nanosensors of this proposal are also active devices and part of the front-end circuit. The resulting integrated system will be monolithic.

The integration of nano-devices with CMOS is challenging due to very different fabrication modalities and material compatibility issues. On the other hand, this presents an opportunity to co-design heterogeneous systems. The theoretical co-design framework (Section 3.1) disclosed here will be used to simultaneously optimize the combination of photon absorption, transduction, amplification, and signal propagation between these stages.

Integration challenges are addressed with research and development on nanomaterial placement (including self-assembly) (Section 3.5-3.7), novel fabrication techniques for connections (Section 3.4), and on augmenting ASIC design tools to include nano-material and interconnect models (Section 3.3). Future development will iterate the co-design optimization with actual material, circuit, and interconnection properties in successive steps.

The technology described in this disclosure goes beyond prior work in both CMOS integration and in photon nanosensors. Previous work on the integration of nanomaterials with CMOS focused on electronics and chemical sensors. In the case of CNTs, initial approaches focused on growing CNTs in-place by chemical vapor deposition (CVD), but limitations of this approach in terms of process compatibility and the ability to control the type of CNT have given preference to solution-based methods. These have been used to demonstrate arrays of chemical sensors and a microprocessor. In the area of CNT photodetectors, most of the work has been on single pixel macroscopic detectors for continuous wavelength (CW) light. Integration with Si technology has focused on heterogeneous integration of optoelectronic logic gates and insertion of CNTs into waveguides to improve responsivity.

### 2. Objectives

We design, prototype and test a uniform pixel matrix (of modest size), with individual pixel performance demonstrating new capabilities of single photon sensitivity with spectral information enabled by low dimensional materials. Specificity of application (photon detection) and materials (CNTs and TMDs) will allow a focus of effort and allow rapid progress, but the techniques and methodology are expected to be broadly applicable to the integration of a wide range of nano-devices on CMOS. For example, the TMD devices will be optimized for photon detection, but different optimizations (beyond the scope described here) could be carried out for chemical sensing, or for logic gates.

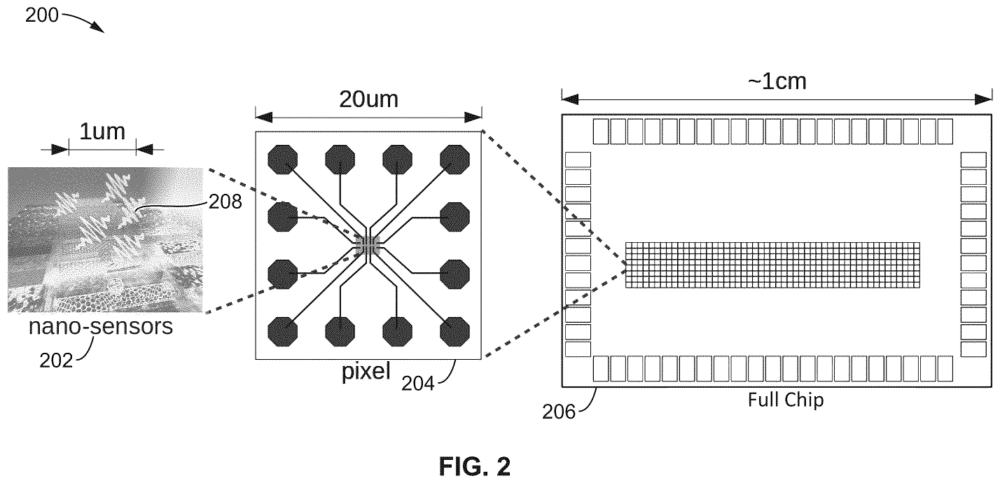

The demonstrator taught here will validate solutions to the problems of integrating novel materials on CMOS in a scalable way. A format with several rows of order 100 pixels each (up to 100 rows for 10k pixels maximum) is sufficient for this purpose. The demonstrator pixels will have a low fill factor (the fill factor is the fraction of a pixel area that is sensitive to light) as shown in FIG. 2, which is adequate to demonstrate functionality. The development will thus represent a foundation upon which a megapixel-scale, high fill factor scientific imager could be designed. (The implementation of megapixel CMOS chip designs is a mature technology that does not need research and development, but requires a large engineering effort.

Refer now to FIG. 2, which is a diagram 200 of how a nanosensor 202 is used to detect individual photons, where the nanosensor 202 is connected to an individual pixel 204, which is in turn connected to a full chip 206. Photon are depicted as waveforms 208 in this diagram.

Small feature size CMOS processes suitable for a high fill factor are also available, but are higher cost and require more design effort to use.

A key new capability of this disclosure is spectral information in every pixel. Rather than measuring the energy of every photon, this will be achieved in a bio-inspired way with wavelength-specific photon “receptors”-nanosensors in the present case. A novel feature (not present in biological systems) is that the nanosensors here are smaller than the wavelength of light being detected. By having multiple different nanosensors within one wavelength, a single photon will be absorbed by the receptor matched to its wavelength with no loss in efficiency or position resolution (see Section 3.1). This feature size is a good match to the inner layers of modern commercial CMOS processes, which are below 10 nm. However, for practical reasons the top (and coarsest) layer of a 180 nm feature size process will be used. This still allows a full demonstration of the nanosensor concept, albeit with low pixel fill factor. The expectation is to be able to pack up to 10 different nanosensors into one demonstrator pixel, which would have dimensions of 20×20 μm². The active area with nanosensors would be a small patch in the center of the pixel.

An estimate for the expected spectral resolution can be taken as the response bandwidth of our photon absorbing nanomaterials, although the ultimate performance will be determined by the co-design framework, since optical absorption needs to be tuned with energy transfer rates and the read-out circuit operation. For functionalization with single chemical layers one can expect λ/Δλ≈20-50 from the optical absorption. Research and development will be executed to improve this with multi-layer hybrid material systems and nano-dots.

In addition to spectral sensitivity, an additional goal is to achieve single photon detection with high quantum efficiency (QE) and low dark counts. Recent theoretical co-design work at the device level suggests that QEs greater than 90% and dark counts less than 10-5 Hz are achievable for single photon detection before considering spectral resolution. The design approaches disclosed here (Section 3.1) will be used to establish the metrics for wavelength resolving detector.

The nanosensors of interest are 1D, 2D, and hybrids combining 0D and 2D, that have the potential to be integrated into devices and systems (Section 3.5, Section 3.6). New techniques will be investigated to synthesize materials in situ with the desired structure for successful integration, including complex (heterogeneous) thin films (Section 3.6).

For nanosensors synthesized separately, innovative approaches to enable scalable assembly will be pursued, including bio-inspired self-assembly (Section 3.7).

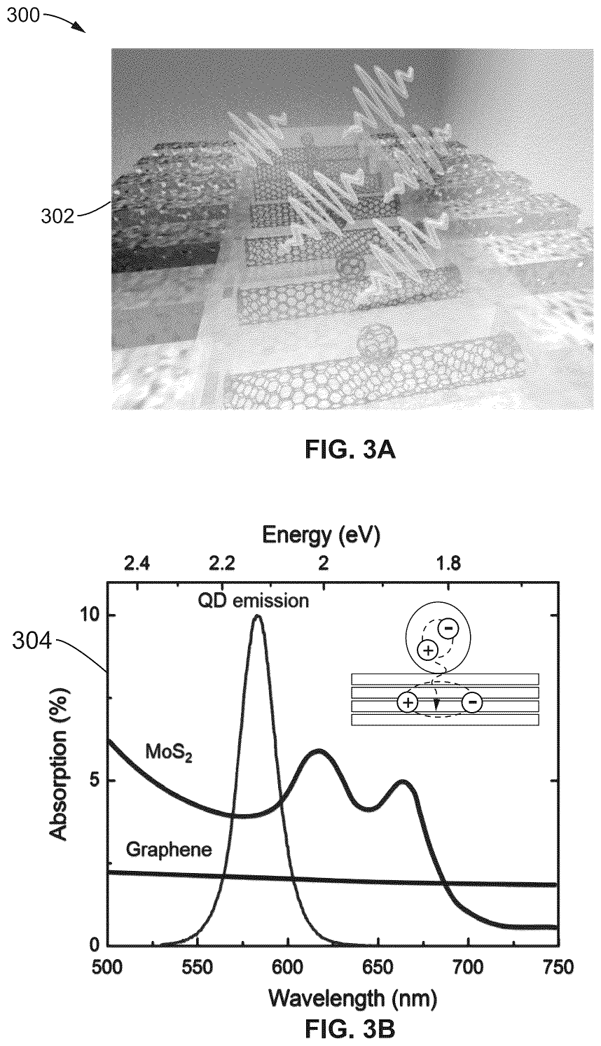

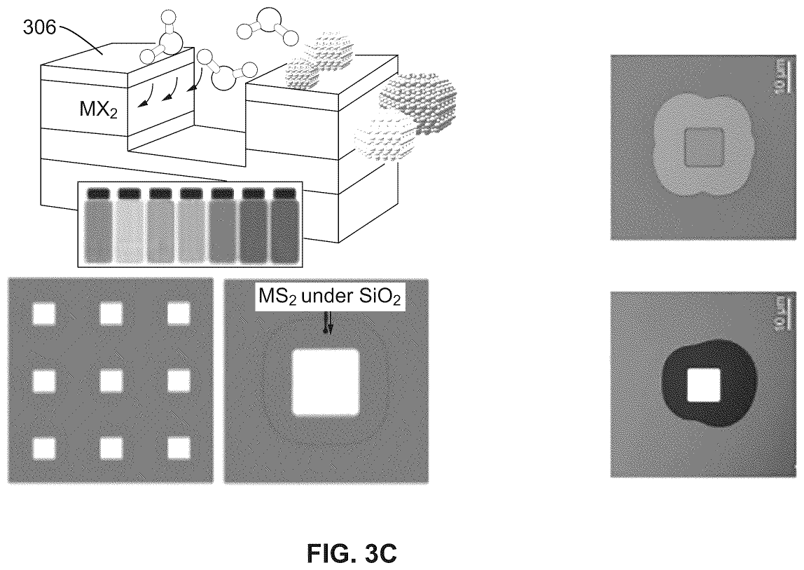

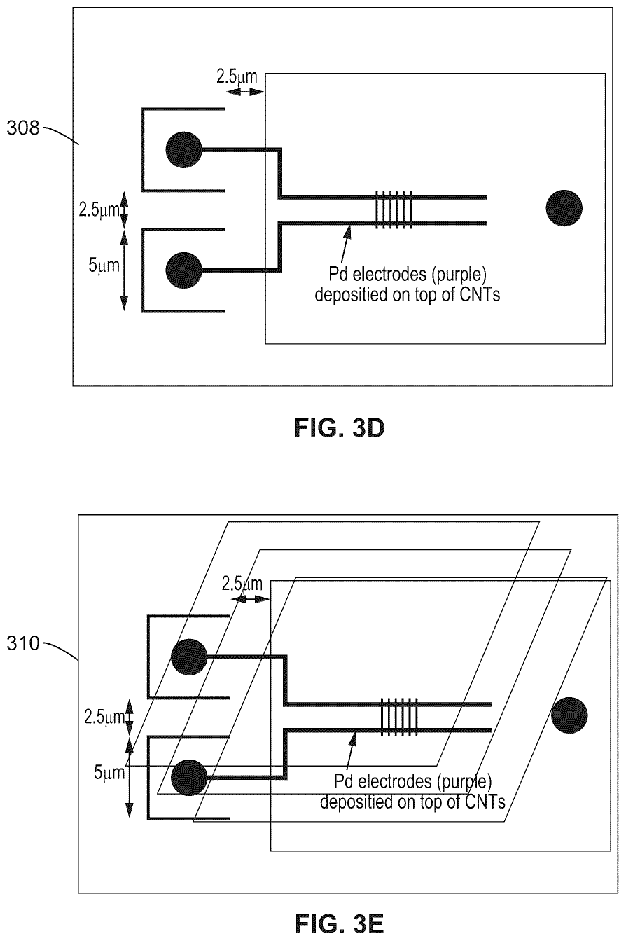

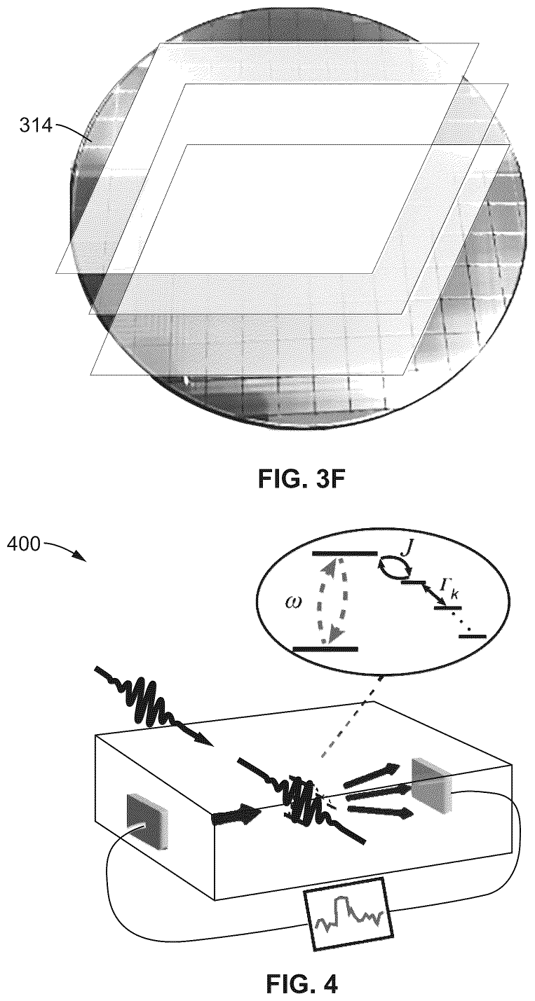

Refer now to FIG. 3A through FIG. 3F, which are a visual representation 300 of a development path. The FIG. 3A top left image 302 represents the present state of the art using CNTs from published works. The top row (of FIG. 3A 302, FIG. 3B 304, and FIG. 3C 306) depicts the evolution with more advanced functionalization of the CNTs in the middle FIG. 3B 304 to a completely new nanomaterial sensing layer FIG. 3C 306 on the right. The bottom row (of FIG. 3D 308, FIG. 3E 310, and FIG. 3F 312) represents the progression from one single nanosensor on one single CMOS pixel on the left FIG. 3D 308, to more complex pixels in the center FIG. 3E 310, to a many-pixel demonstrator chip and wafer scale processing on the right FIG. 3F 312. This single pixel to wafer progression from FIG. 3D 308 to FIG. 3E 310 to FIG. 3F 312 is possible due to the patterning and assembly development path summarized above.

The starting point is the present state of the art in functionalized carbon nanotube photosensitive devices from prior work, along with the codesign framework, plus the challenging step of integrating those devices onto a CMOS ASIC for control and readout (Section 3.5). Future work will build upon that development in two directions: evolution of the nanomaterial system, and evolution of the ASIC and post-processing towards a large system with wafer scale integration of the photosensitive devices. The evolution is needed not only to scale up to a practical imager, but also to establish uniform high efficiency detection with spectral information, and to explore beyond the visible spectrum (ultraviolet UV, infrared IR). The functionalized CNT system that is the initial starting point may not be ideal for all wavelengths of interest and for a scalable fabrication process. As an intermediate step the addition of multi-layer 2D systems will be studied, coupled with OD devices (nanodots), to extend performance of the CNT system. Finally, full 2D systems without CNT devices at all will be investigated, which may eventually have the best scaling and compatibility with CMOS front end processes.

The same CMOS platform will be used for multiple nanosensor systems, down-selected from the materials and integration research and development carried out. The concept of FIG. 2 is one goal of the development. An initial step with a much simpler prototype ASIC and pixel structure will take place first (Section 3.2). The integration will be a back-end process, where the CMOS circuit is fully fabricated first (at a commercial foundry) and the nano-materials are added through in-house post-process steps carried out under this proposal (Section 3.4), taking advantage of existing capabilities at Lawrence Berkeley National Laboratory (LBNL) and Sandia National Laboratory (SNL). This development will represent a new integration process for heterogeneous microelectronics, which in itself will be a valuable product, independently of final sensor performance. Back-end post processing does place limitations on what can be done (for example only processing temperatures below 400° C. are allowed), but also allows heterogeneous integration with low enough cost and lead time to be accessible to a proposal of this scale and to future scientific applications.

While the FIG. 2 concept is the culmination of the plan disclosed here, there are important intermediate goals. Many of these will be significant stand-alone results. The extension and application of the theoretical co-design framework to produce practical devices will result in a recipe to apply the same method to other problems, for example chemical sensing. Full physical modeling of electrical signals in functionalized CNT, 2D, and 2D-0D hybrid nanosensors, and the integration of that code with standard IC design simulation tools (Section 3.3), will be of broad interest to any heterogeneous design effort involving CMOS. The scalable electrical interconnection of CNTs and 2D/0D devices to the underlying CMOS circuit should be broadly applicable to novel devices other than sensors. In fact, the CNTs themselves are transistors, as are many 2D devices. A similar argument applies to lithographically patterned synthesis (Section 3.6) and to self-assembly (Section 3.7) methods.

### 3. Materials and Methods

### 3.1 Theoretical Co-Design Framework

Refer now to FIG. 4, which is an illustration 400 of the processes that typically occur during photodetection.

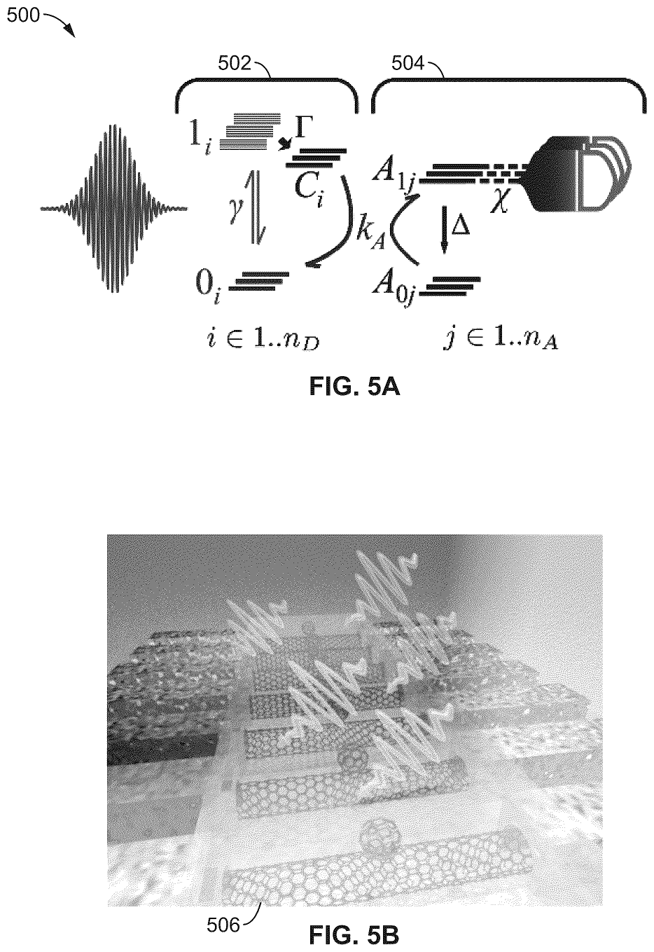

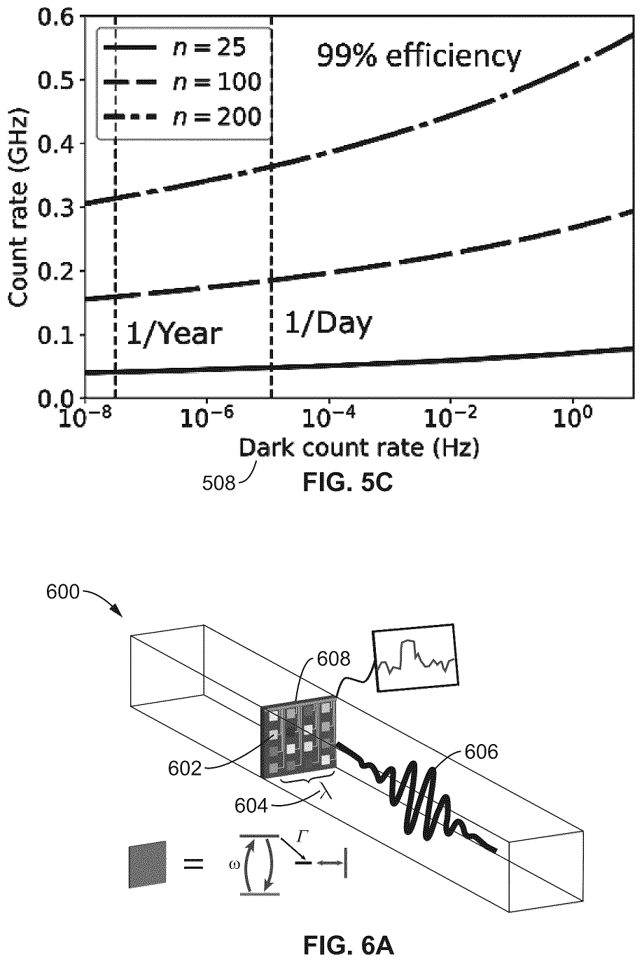

Detecting photons is a complex process that involves several steps, from the initial absorption process to the eventual generation of an electronic signal (FIG. 4). Existing models of photodetection have treated this process sequentially, for example by separately optimizing optical absorption and the read-out electronics. However, in the case of single photon detection where stringent metrics need to be achieved simultaneously (e.g., high efficiency, low dark count rates, low jitter) the sequential approach can only achieve incremental improvements in performance. Recently, a new approach for photodetectors, following co-design principles has been developed, where the absorption process, the transduction, and the amplification are all treated as part of one coupled system. The approach here is thus a theoretical physics framework for the co-design principle. This framework has been shown to not only establish the fundamental performance limits of photodetectors, but that it can also be used to design entirely new types of photodetectors with new functionality. At a high level, the framework uses quantum master equations to predict the quantum statistics of photodetection. This approach is applied to general detection architectures as shown in FIG. 5.

Refer now to FIG. 5A through FIG. 5C. FIG. 5A is an illustration 500 of the general architecture for optimal photodetection, where 502 refers to the donor subsystem and 504 refers to the acceptor subsystem. FIG. 5B is an illustration 506 of an example of system that realizes the general architecture. FIG. 5C is an illustration 508 of the predicted performance of this system when 99% efficiency is required.

There, a subsystem D 502 absorbs the photon and quickly transfers the excitation to another subsystem A 504 through an incoherent energy transfer process. The transferred excitation is then monitored using an amplification process X. The co-design of this system predicts that low-dimensionality materials are ideal for the D and A subsystems, more precisely, materials with a functional form for the density of states that resembles those of low dimensional materials. Indeed, this framework leads to the detector design shown in FIG. 5A through FIG. 5C with a bi-molecular system surrounding a carbon nanotube electronic transport channel, predicted to have high performance.

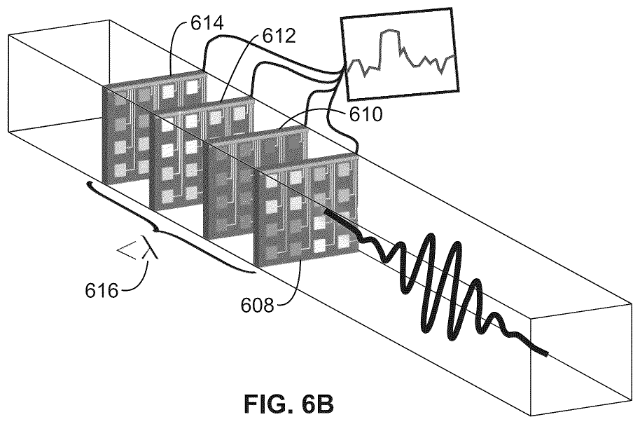

Here we extend the above model to go beyond co-design within the device and include the integration with the CMOS electronics. This is important for several reasons: first, because of the nature of photon wave packets and the need to retain timing information, it is critical to match the time-dependent photo-physics and current response in the device with the high-frequency properties of the signal propagation outside of the device and its eventual interaction with the CMOS electronics; second, it has been predicted that new types of detector functionalities could be performed if dense arrays of nanoscale devices could be disposed within the wavelength of the photon. Realizing such a complex architecture will require new circuit topologies and CMOS timing schemes to properly address and read-out the devices. Such work will involve several facets:
(a) Specialize the device-level co-design framework to the materials (CNTs, 2D materials) considered in this proposal. Informed by fundamental materials and physics experiments (Section 3.6), identify combinations of channel and absorber materials for high performance. Include specific device geometry (e.g., electrical contacts, dielectrics).
(b) Include the signal propagation in the circuit to broaden the co-design perspective. This will be done using the ARTEMIS code development (Section 3.3). It is anticipated that matching the device time dependent signal to the outside electronics will be essential to reduce losses and dispersion. In turn this will require matching the device properties and the signal propagation topology and materials. Once this information is available, co-design of both the circuit topology and the device will be used to achieve high performance.
(c) Co-design a new type of single-photon photodetector that will simultaneously achieve frequency resolution, high efficiency, low dark counts, and low timing jitter. This effort will bring together several efforts because a priori the best architecture for such a detector is not established. A potential approach is shown FIG. 6 where multiple nanoscale devices are included within the wavelength of the photon.

Refer now to FIG. 6A, which is an illustration 600 of a potential design for a frequency-resolving detector, where several nanoscale devices 602 are within the wavelength 604 of the photon 606. In this FIG. 6A, al nanoscale devices 602 are contained within a single plane 608.

Refer now to FIG. 6B, which is an illustration of a potential design for a frequency-resolving detector, where several nanoscale devices are within the wavelength of the photon within the single plane 608 of FIG. 6A, and three additional planes 610, 612, and 614 arrayed behind the initial plane 608. All sensing planes are disposed within the desired sensor wavelength 616.

Designing this system will require careful considerations of the circuit topology in order to maximize signal coverage while also realizing uniform signal delays and minimizing cross-talk.

### 3.2 ASIC Design And Production

The design and production of an ASIC (Application Specific Integrated Circuit) is a long lead time item and drives the timeline for the demonstrator devices to be produced as a goal. It is anticipated using a 180 nm bulk CMOS process will be advantageous, because it has fast fabrication turn-around, modest cost, and can recycle many extant circuits from other projects. This not only saves time, but lowers technical risk for the new design. A significant issue is the flexibility available for design of metal pads on the surface of the ASIC, which enable functional connectivity to the nanomaterial layers added through post-processing (Section 3.4). An IC process has standard pads and very specific design rules for custom pads. The special pads needed for this project will violate design rules. A process exists for waiving design rule violations with foundry approval, which must be started by investigating what design rules must be violated and if those violations will be allowed. If suitable pads cannot be produced in this preferred process, then a different one must be selected at the start of the project.

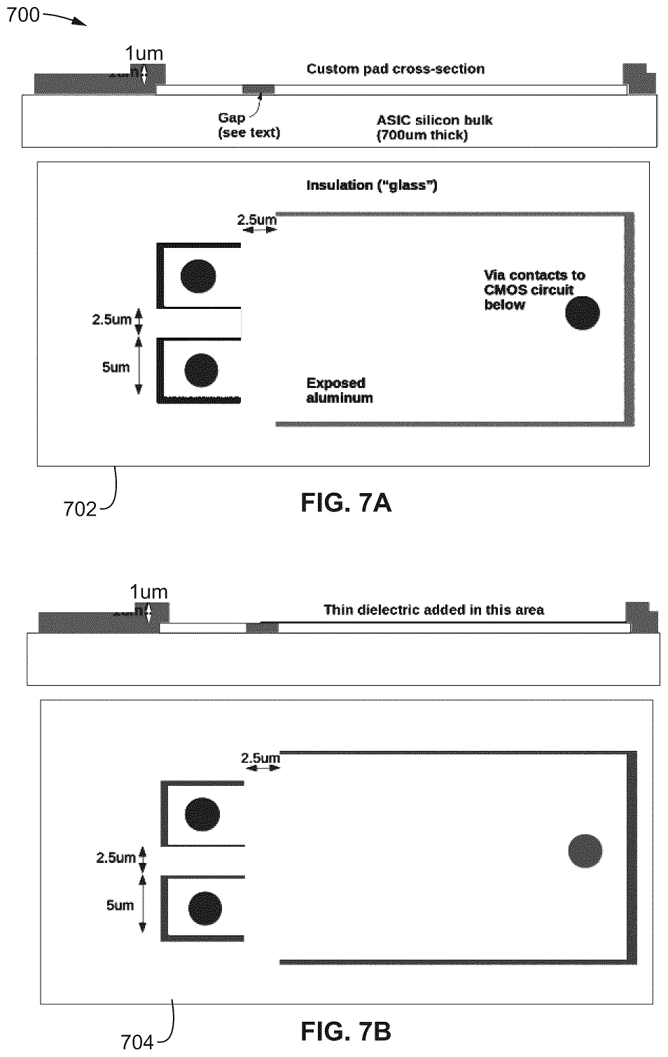

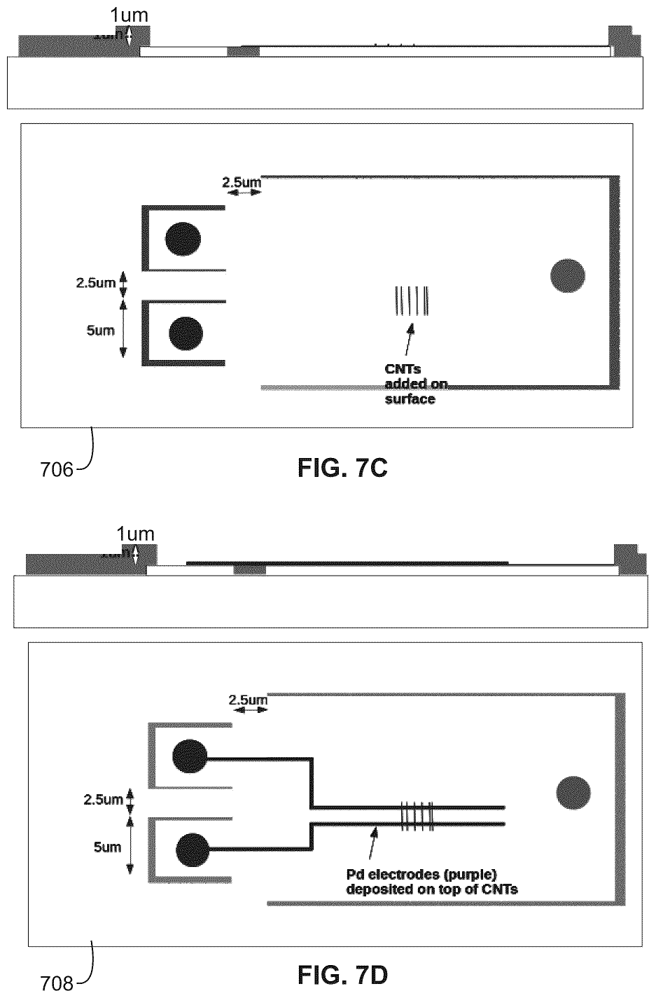

Refer now to FIG. 7A through FIG. 7D, which are illustrations 700 of a concept for integration of CNTs on the CMOS ASIC.

FIG. 7A is a layout 702 of a pad as-built by a CMOS foundry. In this FIG. 7A, as well as the succeeding FIG. 7B, FIG. 7C, and FIG. 7D, the top image shows the device cross section while bottom shows layout view.

FIG. 7B 704 is an addition of a thin dielectric layer on large electrode that will form the carbon nanotube (CNT) gate.

FIG. 7C 706 is an addition of CNTs to gate electrode area.

FIG. 7D 708 is a deposition of Pd electrodes to connect CNTs to integrated circuit (IC) inputs.

FIG. 7A through FIG. 7D show schematically how CNTs will be integrated starting from the as-purchased ASIC. This is conceptual and may not be what the pads actually look like, but it illustrates the above point. A CNT is about 1μ m long and requires three connections: an A/C coupled gate and D/C coupled source and drain. While the minimum feature size of the CMOS process is 180 nm, this applies only to the transistor and lower metal levels. The top metal where pads are patterned has much larger features. The CNTs must therefore be connected to much larger structures. The gate electrode is formed as a blanket structure (an infinite plane as far as the CNT knows), which is the large metal rectangle in FIG. 7A. This pad must be covered with a very thin insulator (FIG. 7B) to achieve the A/C coupling-much thinner than the protective, insulator “glass” on the chip surface. The thickness of this insulator layer dictates how much gate voltage will be needed. From prior experience, a 10-50 nm thickness will require about 10 V. The aim here is for 10 nm or less (refer to Section 3.4) in order to avoid the need for a higher than 6 V in the IC. Any candidate CMOS processes will have 3.3 V rated transistors, and voltage doubler circuits are fairly standard, while a higher voltage is more challenging or requires a higher voltage (HV) process.

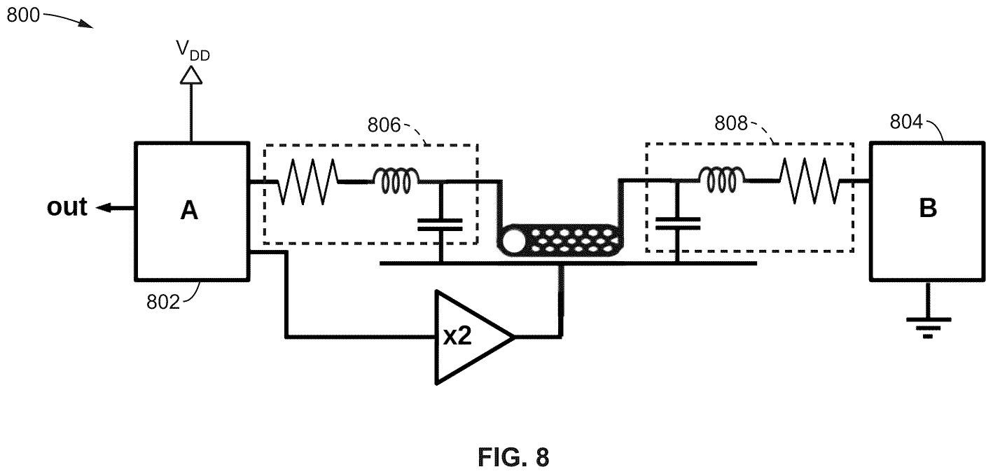

Once the gate electrode has been insulated, CNTs can be placed on the surface (FIG. 7C and Section 3.5). Their source and drain must finally be connected by adding a suitable patterned metal, for which Pd is commonly used (FIG. 7D and Section 3.4). This metal must cross the gap shown in FIG. 7A, which is not a standard pad feature. Ways to implement this gap involving design rule violation waivers and/or post processing steps will be explored. The electrical properties of these added metal connections will have to be extracted and included in circuit simulation (Section 3.3). A diagram of the expected circuit is shown in FIG. 8. The R, L, and C elements shown are parasitic. Because the interconnect structures are much larger than the CNT device, these parasitics are expected to very significantly affect circuit performance, and the design must incorporate them from the start. The blocks A and B are the amplifier and driver circuit elements. As a minimal example, A could be a load with a cascode transistor and B could be simply a connection to ground. In this simple example A would also contain gate bias voltage source for the CNT, with a voltage doubler (“×2”) to drive the CNT gate. The real circuit will be more complex, possibly differential (with outputs from A and B), and with dynamic control of the CNT gate including using it to inject calibration signals. Additionally, 2D and hybrid nanoscale devices may have different terminal requirements than the CNT. These elements will be included in the co-design framework of Section 3.1, which will in turn produce specifications for amplifier design. Note that no photon signal input path is shown in FIG. 8. The energy transfer from light to charge on the CNT surface is discussed in Section 3.5, and for 2D and hybrid devices in Section 3.6, and also included in the co-design framework.

The ASIC development will take place in two stages with separate fabrications as given in Section 4. The second stage will lead to a device resembling the concept of FIG. 2. The first stage will make use of Multi Project Wafer (MPW) fabrications with the aim of validating all the needed pad structures and special circuit elements, such as voltage step-up converters, plus a first version of the single pixel circuitry. This will not yet be an imaging matrix, but a collection of circuits and a few pixel structures with analog outputs.

The MPW provides only diced chips (not wafers) of modest size (10-20 mm²). The ability to carry out integration post-process steps on these chips will be limited. All possible steps will be validated, as well as the compatibility with all steps. For example, if a wafer processing step that cannot be done on a single chip requires time at a moderate temperature, laser annealing, chemical treatment, etc., the MPW chips can still be validated as not being degraded by such exposures. The second (final) ASIC stage will involve the production of full wafers. This will permit the production of larger chips (e.g., 2×2 cm²) and allow the carrying out of wafer post-processing steps. The actual processing of wafers can be validated with silicon blanks ahead of time.

### 3.3 Merging Simulation of Nanosensors and ASIC Design Tools

CMOS circuit simulation is an indispensable part of any modern design. Manufacturers provide extremely detailed simulation models for the devices in their process, to be used with specific circuit simulators. These are generally based on SPICE for the lowest level simulations that are carried out. Incorporating new active devices that will be part of the same circuit along with CMOS transistors requires the same level of detail and full compatibility with the commercial simulator codes used. While transistor models have typically been extracted from parameter analyzer measurements on a large variety of device geometries and test conditions, this approach would be prohibitive for initial modeling of new nano-devices, where generating a large variety of test devices and making hundreds of measurements on each would represent a large effort and take a long time. Here, reliance on physical modeling will instead start from the device structure using ARTEMIS (Adaptive mesh Refinement Time-domain ElectrodynaMics Solver).

ARTEMIS is a new time-domain electrodynamics solver developed in the Computational Research Division at LBNL that is fully open-source and portable from laptops to many-core/GPU exascale systems. The core solver is a finite-difference time-domain (FDTD) implementation for Maxwell's equations that has been adapted to conditions found in microelectronic circuitry. This includes spatially-varying material properties, boundary conditions, and external sources to model specific target problems. In order to achieve portability and performance on a range of platforms, ARTEMIS leverages the developments of two DOE Exascale Computing Project (ECP) code frameworks. First, the AMReX software library is the product of the ECP co-design center for adaptive, structured grid calculations. AMReX provides complete data structure and parallel communication support for massively parallel many-core/GPU implementations of structured grid simulations such as FDTD. Second, the WarpX accelerator code is an ECP application code for modeling plasma wakefield accelerators and contains many features that have been leveraged by ARTEMIS. These features include core computational kernels for FDTD, an overall time stepping framework, and I/O.

Refer now to FIG. 8, which is a diagram 800 of an expected circuit for integrated CNTs. Boxes A 802 and B 804 are CMOS circuit blocks, while the discrete passives 806 and 808 are parasitic.

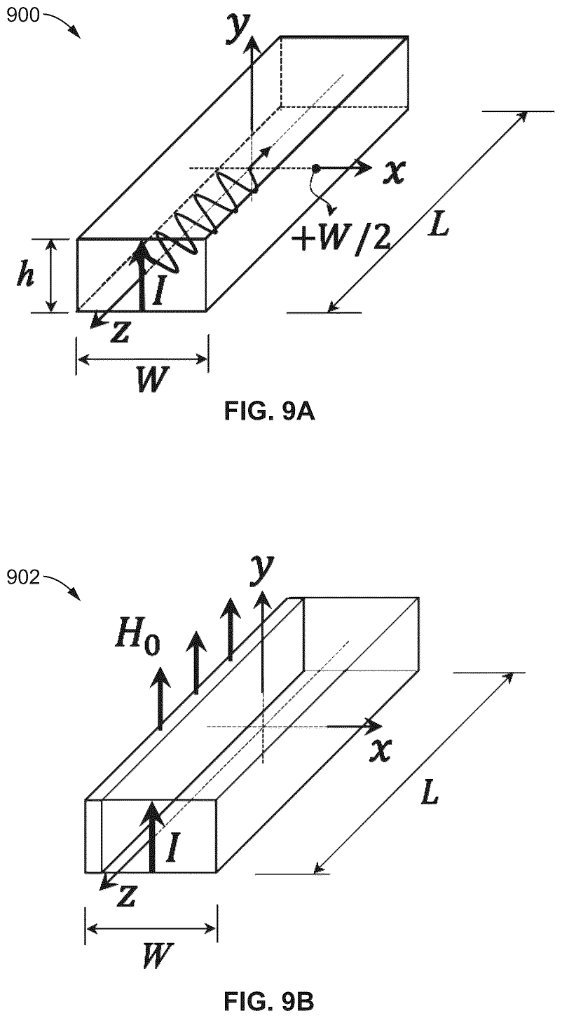

Refer now to FIG. 9A and FIG. 9B, which are illustrations of waveguide structures modeled by ARTEMIS. Here, an input current waveform is supplied and the attenuation of the signal as a function of length is modeled. In FIG. 9A, an air-filled waveguide 900 is modeled. In FIG. 9B, a waveguide with a slab of magnetic material inserted to modify the response of the device is modeled 902.

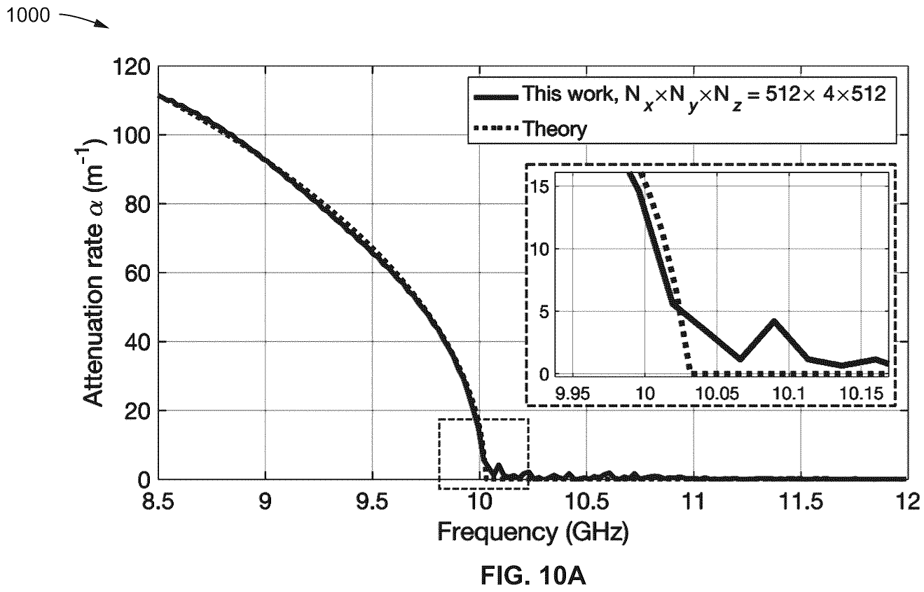

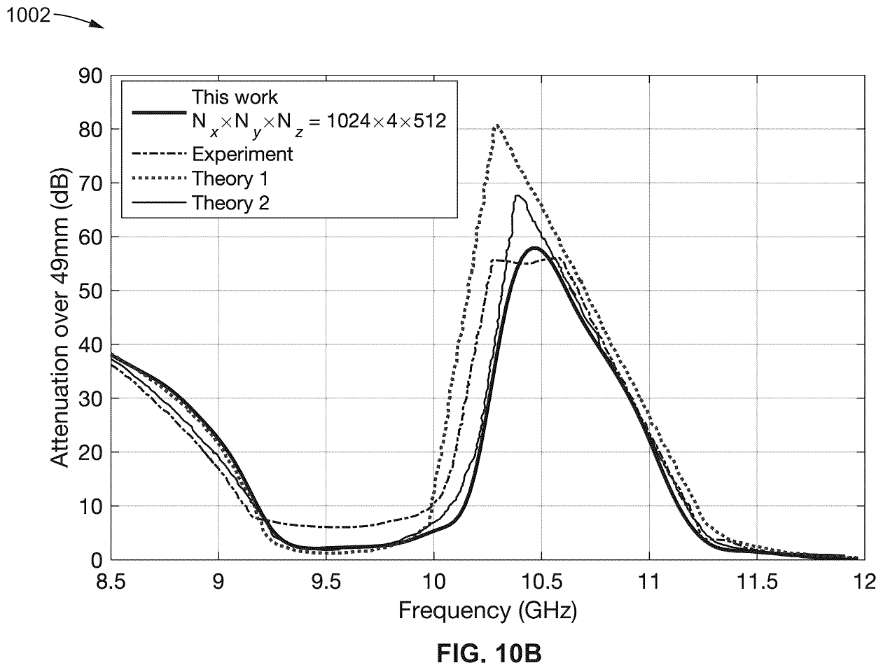

Also refer now to FIG. 10A and FIG. 10B. FIG. 10A is an attenuation spectrum 1000 computed using ARTEMIS for the waveguide structures of FIG. 9A and FIG. 9B where the waveguide is filled with air. FIG. 10B is an attenuation spectrum 1002 computed using ARTEMIS for a magnetically tunable structure.

In FIG. 9A, FIG. 98B, FIG. 10A, and FIG. 10B, two waveguide structures are described, and the resulting attenuation spectra measured with ARTEMIS. Using the ARTEMIS python-style function interpreter, more advanced structures can be defined containing many different material types using different geometrical configurations. Additionally, the GPU capability of the code provides extreme speed, as a GPU build offers a 59× speedup over the host on a node-by-node basis. Thus, using high performance computing (HPC) resources will allow for high-resolution and rapid prototyping of various configurations with different geometries and material properties. It should also be noted that algorithmic flexibility is available for additional physics (previously developed magnetization model and current plans for superconducting materials). The ARTEMIS model can be validated with a few measurements of existing devices and then used to calculate the response in the full range of conditions needed.

In order to derive the lumped element parameters in FIG. 8, the ARTEMIS code will be used to perform full physical modeling of the electric and magnetic fields of the ASIC structure in FIG. 7A and FIG. 7B. The calculation of the current/voltage response of the structure from the simulated electromagnetic signals, from which will be extracted appropriate values for R, L, and C to be used in the corresponding higher-level device simulations. ARTEMIS can be used to rapidly test different material and geometrical configurations to determine the system response. The results from the higher-level circuit simulations will also be used to hone in on more optimal design, and in turn inform both materials and fabrication as to the optimal configurations of the ASIC structure. In this co-design approach, transmitting and receiving information will occur from levels above and below the physical modeling capability used herein.

### 3.4 ASIC Post-Processing

The ASIC-CNT integration sequence shown in FIG. 7A through FIG. 7D requires the growth of an approximately 10 nm insulator layer on top of a metal pad that is manufactured as part of the ASIC in the commercial CMOS foundry. The metal pad material is primarily aluminum but need not be substantially pure. The exact composition is often not revealed. The surface contaminations often occur in these foundry processes and after short-term storage. Therefore, it is a preferred approach to first remove the surface contamination using an appropriate etchant, then deposit a high-quality pure metal layer, followed by the growth of a metal-oxide layer to serve as the gate insulator. Substantially pure aluminum is a good candidate metal for this procedure. The metal deposition shall be masked to only cover the ASIC pad. Considering the constraints such as the maximum process temperature, other metals and materials will be investigated for this purpose. The thickness of the metal layer is not important but the oxide/insulator layer thickness must be precisely controlled.

Pd electrodes connect the ends of CNTs to the source and drain readout of the ASIC (FIG. 7D). In an initial demonstration, the first approach is to use electron beam lithography and evaporation processes to define and fabricate the electrodes. Electrode designs together with lithographic overlay schemes that can utilize registration marks from the CNT fabrication steps will be explored and tested for accurate electrode alignment to the CNTs. As high-energy electrons, high temperature, and certain chemicals can damage the CNTs, the lithographic process will be tailored to maintain the integrity of the CNTs as well as other components on the device at that stage. The deposition process will be developed under similar considerations as well. Deposition morphology and layer thickness uniformity, which can affect the device performance, will be some of the other parameters for which the deposition process will be optimized. Electrode contact yields with the CNTs and electrical performance will be evaluated with imaging and electrical characterization tests. The complete post processing development will be based on conventional fabrication equipment and processes. Even though the electron beam lithography patterning cannot be scaled up easily, the other processing development (and possibly the overlay schemes) would be highly extendable to wafer-scale manufacturing.

The above developments generally require a specific format (for example specific diameter wafers) for the processing equipment used. Blank wafers will be used for development as will also re-formatting of single chips and wafers using known techniques from semiconductor processing readily accessible from local vendors, such as wafer re-sizing, thinning, chip on wafer embedding, etc.

### 3.5 Functionalized Carbon Nanotube Devices

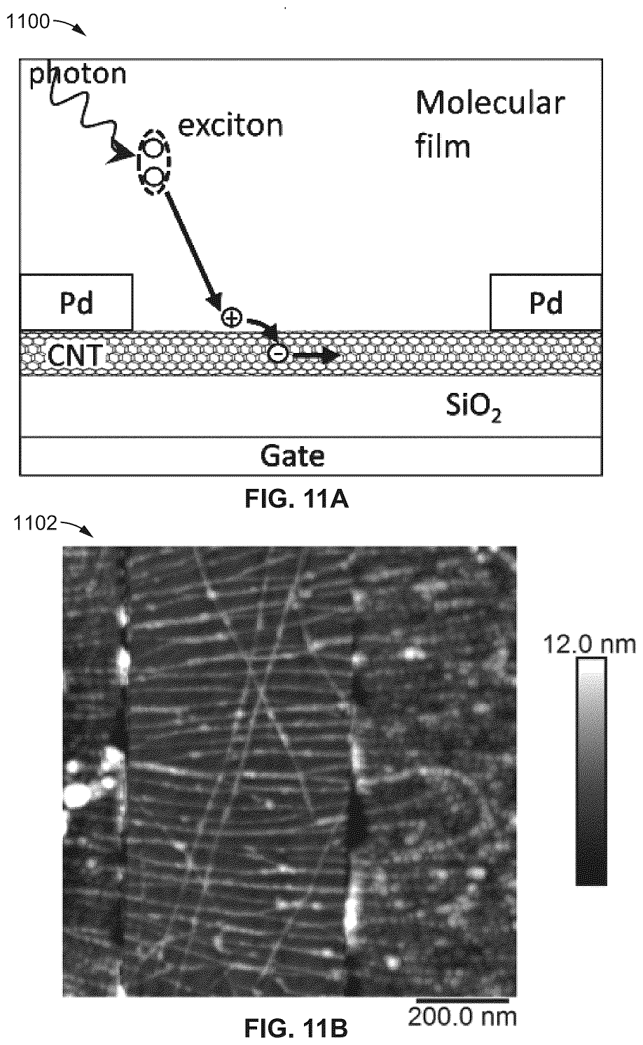

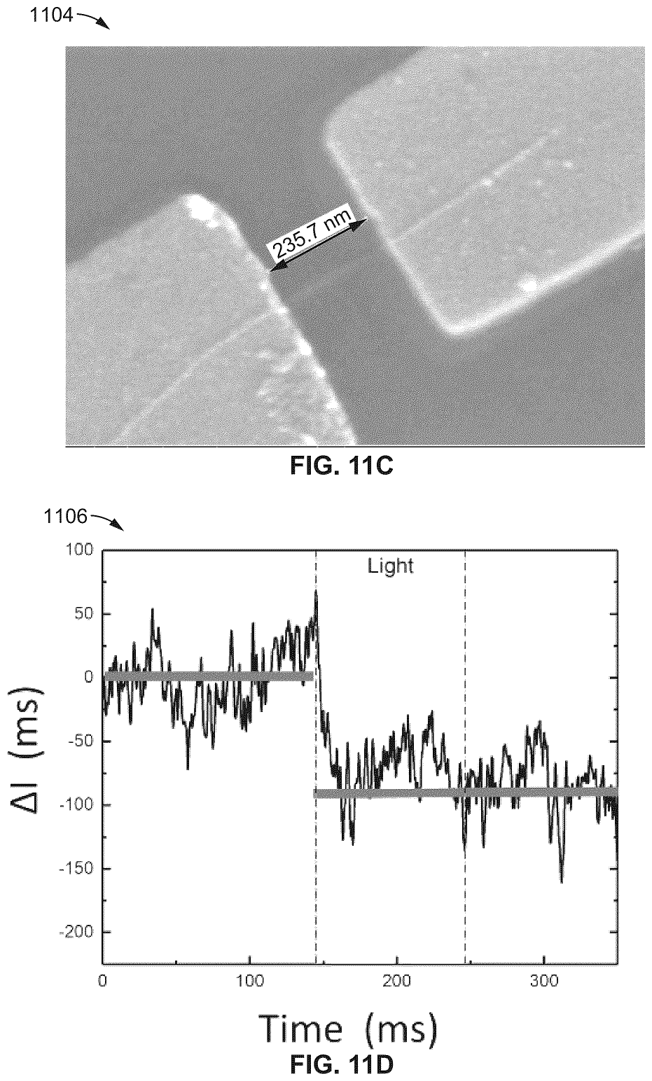

Refer now to FIG. 11A, FIG. 11B, FIG. 11C, and FIG. 11D. FIG. 11A is an illustration 1100 of the photodetection mechanism. FIG. 11B is an atomic force microscope (AFM) image 1102 of aligned CNTs in a transistor channel. FIG. 11C is a scanning electron micrograph (SEM) 1104 of a device with an individual CNT. FIG. 11D is a graphical example 1106 of photo-response to a light pulse.

The co-design framework of Section 3.1 suggested a photodetector pixel consisting of a thin absorbing layer that transfers the photo-excitation to a transport channel whose conductance can be efficiently modulated, leading to gain. Theoretical predictions indicate that a CNT channel functionalized with molecules could form such a system. To test this hypothesis, photodetection pixels consisting of CNT transistors were fabricated (using commercially available semiconducting CNTs) functionalized with different molecules (FIG. 11A through FIG. 11D) and demonstrated high gain at room temperature, and the detection of as few as 5-8 photons per CNT.

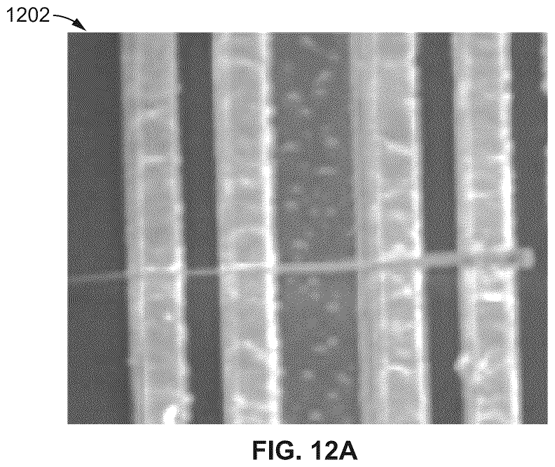

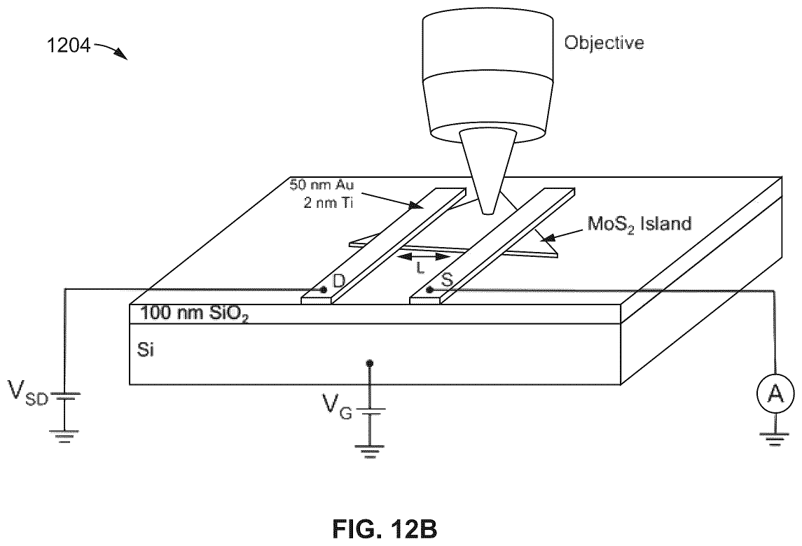

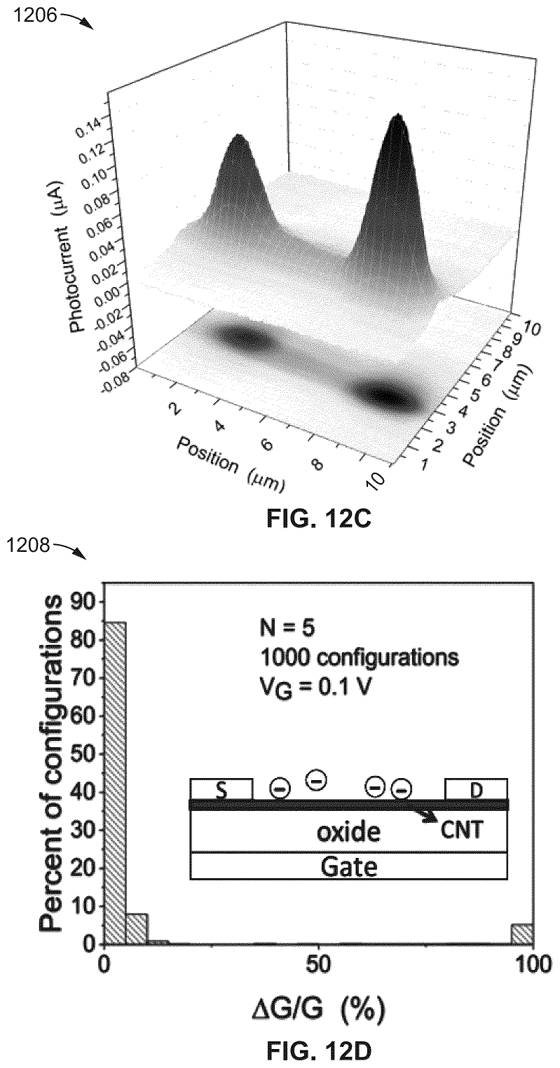

Photons are absorbed by the thin molecular layer, creating an exciton that diffuses to the molecule-CNT interface where it is dissociated (FIG. 11A). Either the hole or electron are transferred to the CNT and carried away, while the remaining charge is trapped near the CNT and modulates its conductance. Such devices can be fabricated with arrays of CNTs (FIG. 11B) or with an individual CNT (FIG. 11C). In the case of arrays, thin films of C₆₀ and P₃HT have led to the detection of 40-50 photons in the array, corresponding to 5-8 photons per CNT. Initial results with a device consisting of a single CNT in the channel covered with C₆₀ has led to the detection of 200 photons at room temperature (unpublished). This result indicates that scaling to smaller devices can lead to improved sensitivity, and thus it is expected that P₃HT would scale to a few photons. These demonstrations show the value of pursuing nanomaterials for photodetection, but to improve the performance several challenges need to be overcome. Such challenges can be addressed with detailed fundamental science studies of the photo-physics in the molecular/CNT hybrids and with the integration with CMOS:
(a) As discussed in Section 3.1, performance relies on control of energy pathways and time scales throughout the device materials. While there have been studies of the photo-physics of molecule/CNT hybrids, the particular processes relevant to photodetection have not been studied in detail. Detailed optical characterization will be employed to study the non-equilibrium photo-physics and extract the rates that enter the co-design modeling framework. Device response will be compared with these rates to provide a detailed understanding of the governing processes.
(b) Integration on CMOS platforms is the main goal, but also enhances overall research and development. The CMOS electronics provide an exquisite measurement platform for the device properties and the photo-response. For example, it is anticipated that the noise will be reduced compared to typical measurements with probe stations, and that ultrafast electronic measurements will allow the probing of the short-time response in more detail. Co-design of the sensor and the CMOS electronics will be critical to minimize noise, utilize the right measurement bandwidth, and reduce dispersion.
(c) Initially, CMOS-integrated devices will be fabricated with individual CNTs and will then be moved to CNT arrays. These different designs will allow for the probing of the co-design space and determine the optimal design. Surface preparation, dielectric, and metal layer details will be fed back to the post-processing effort. For individual CNT devices solution-based deposition of semiconductor-rich CNTs will be used as well as e-beam lithography to contact individual CNTs. At first, P₃HT will be deposited to assess the device performance when scaled to individual CNTs. Scaling up to more complex CNT arrays will make use of Section 3.7 and 3.4 techniques with the ultimate goal of realizing a frequency-resolving detector through placement and functionalization with different species (e.g., quantum dots).
(d) The photo-response performance will be tested using SNL and LBNL facilities. This includes the ability to perform scanning photocurrent microscopy to probe the spatial response of the devices by rastering the focused light over the device area (FIG. 12). While this technique has been applied at larger light intensities to study many nanomaterials-based devices, the case of single and few-photon detection is unique in that variations in the position of a single charge (or a few trapped charges) generated from the photo-response process could lead to statistical variations in the device performance.

Refer now to FIG. 12A through FIG. 12D. FIG. 12A is a SEM image 1200 of individual nanowires between electrodes.

FIG. 12B is an illustrated schematic 1202 of a scanning photocurrent approach illustrated for a 2D material.

FIG. 12C is a single photon counting module (SPCM) map 1204 for the nanowire of FIG. 12A.

FIG. 12D is a plotted simulation 1206 of discrete charge effects on photo-response behavior.

### 3.6 2D And Hybrid Nanoscale Devices

Two-dimensional semiconductors like 2D transition metal dichalcogenides (TMDs) are attractive candidates for nanoscale photodetectors because of large absorption cross sections, high tunable gain, and low dark currents. They can be prepared layer by layer with nanoscale precision in their thickness with tunable direct to indirect bandgap. Work will continue on (1) lithographically defined synthesis of TMDs for CMOS integration, and (2) development of TMD hybrid heterostructures for use as photosensitive materials with tailored spectral sensitivity.

While there has been much recent progress growing 2D TMDs for integration into electronic devices, large scale integration remains a challenge, especially when it comes to multilayer or lateral heterostructures. Synthesis of high-quality TMDs generally needs temperatures above 600° C., whereas back-end integration on CMOS (as is planned) is limited to below 400° C. There are two possible solutions: lowering the synthesis temperature, or transferring materials post-growth. Both approaches will be explored, each of which has its own challenges. An increase of crystalline quality at low synthesis temperature using a semi-encapsulated reaction environment will be attempted. Alternatively, standard high-temperature processing will be used to create patterned heterostructure device components on blank wafers and transfer the full patterns to the CMOS wafers post-synthesis.

Both of the above approaches will use the recently developed “lateral conversion” synthesis method for 2D TMDs, in which a reactive layer of material, sandwiched between two layers of non-reactive material, is chemically converted starting from an exposed edge. Lateral conversion enables the synthesis of TMD layers and heterostructures in lithographically defined patterns that are encapsulated in a protective layer.

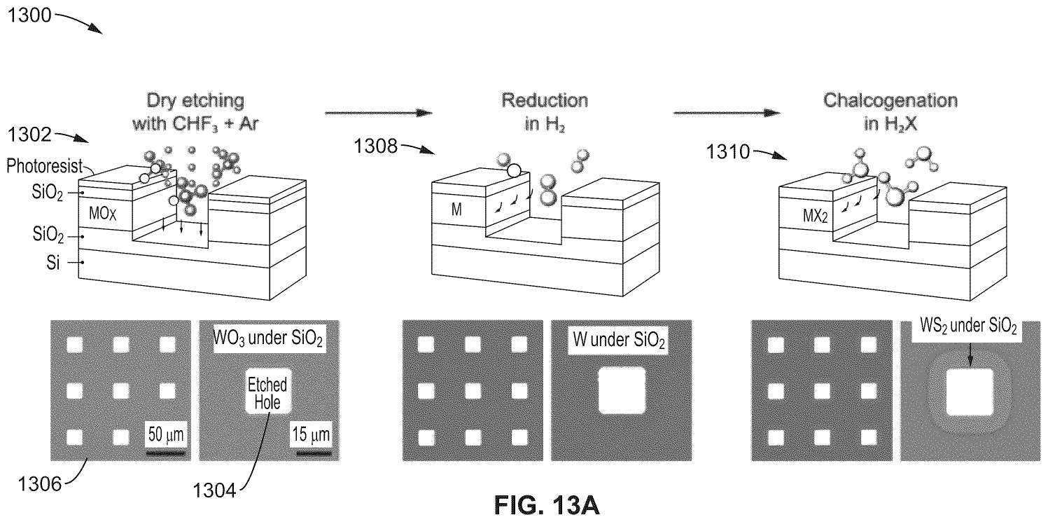

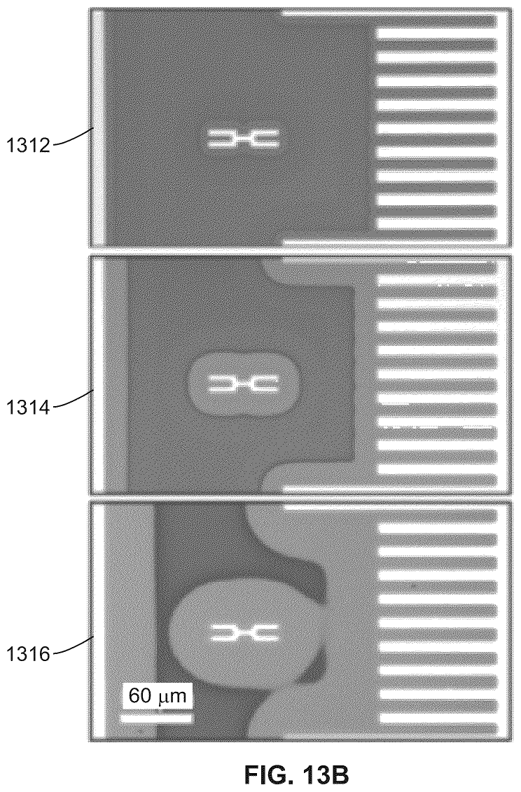

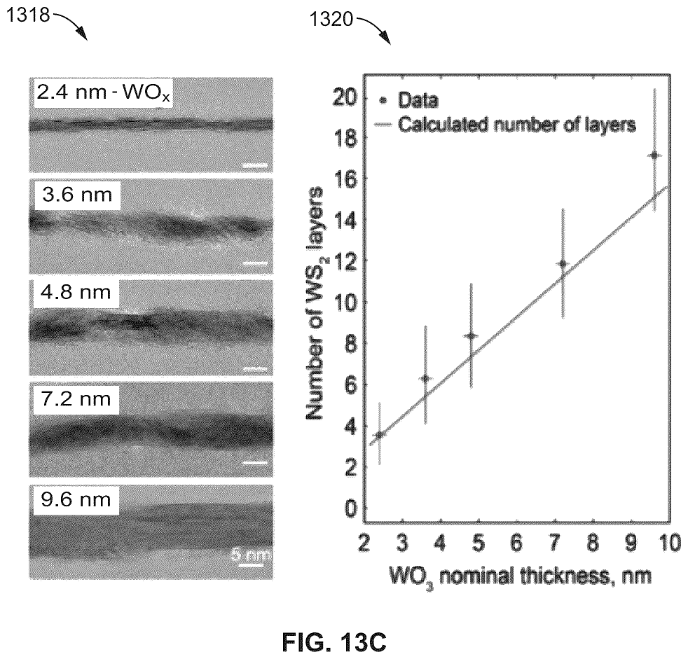

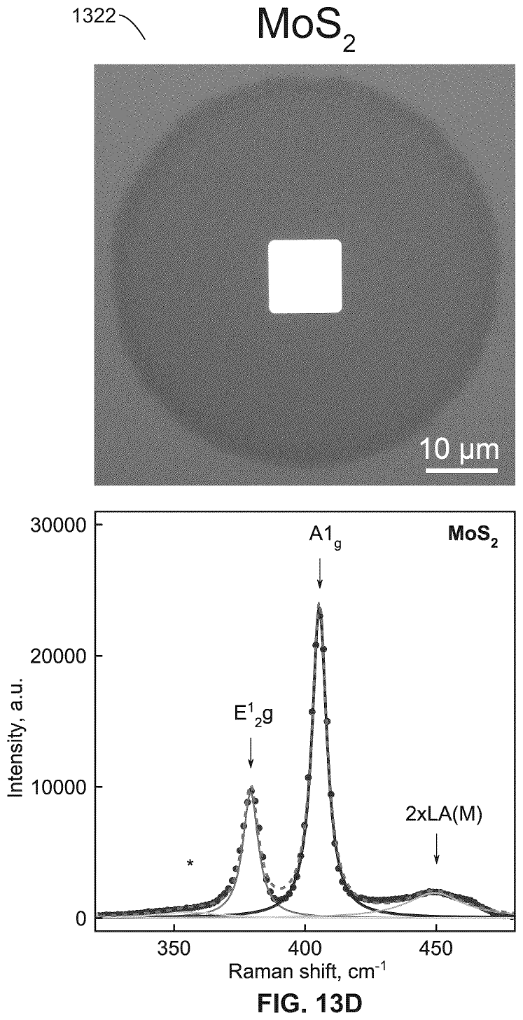

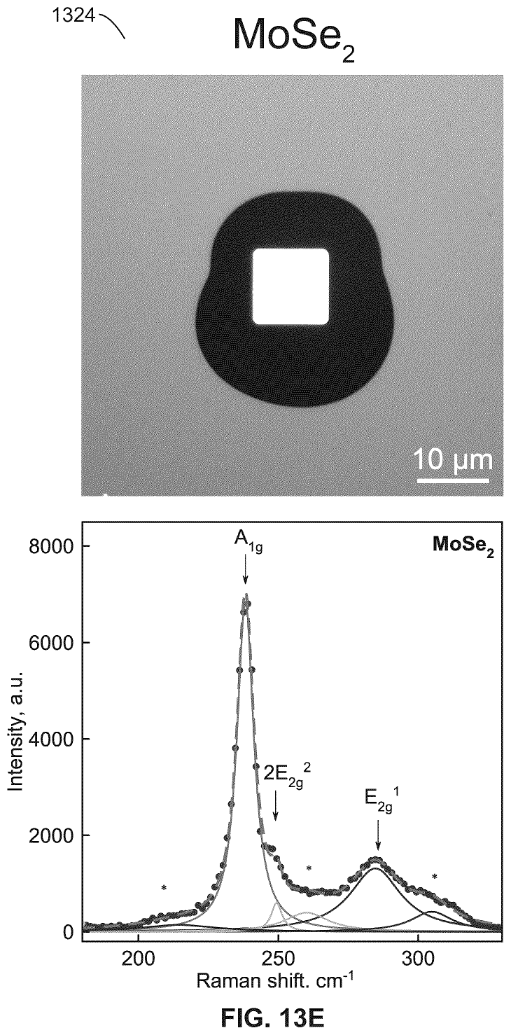

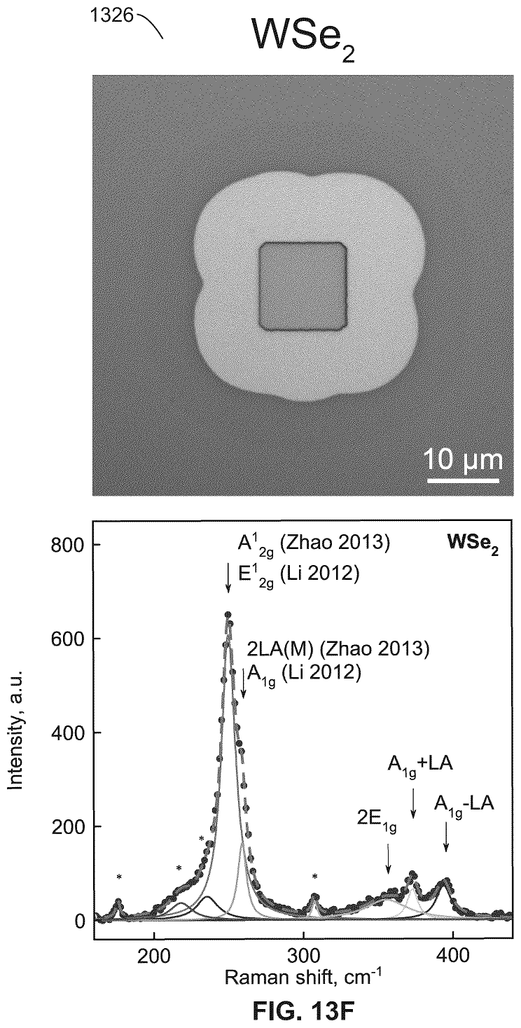

Refer now to FIG. 13A through FIG. 13D-3. In FIG. 13A a schematic illustration 1300 is shown of the process of synthesis and characterization of lithographically patterned transition metal dichalcogenide (TMD) WS₂ structures grown using the Lateral Conversion (LC) method, with the device 1302 shown first. The top view of the device is shown 1304, and finally a wafer of several devices shown 1306 after dry etching with CHF₃ and Ar. In the next grouping 1308, we see the same devices previously shown after reduction in H₂ 1308, and finally after chalcogenation in H₂X 1310.

FIG. 13B shows optical microscope images 1310, 1312, and 1314 of lithographically patterned structures converted for different amounts of time, demonstrating the ability to produce arbitrary shapes and control the LC extent.

FIG. 13C shows transmission electron micrograph (TEM) cross-section images and plot showing the number of WS₂ layers as a function of WOₓ thickness with thicknesses of 2.4, 3.6, 4.8, 7.2, and 9.6 nm 1318 and their corresponding graphical data fits 1320.

FIG. 13D, FIG. 13E, and FIG. 13F show optical images (top) and corresponding Raman spectrum (bottom) of MoS₂ 1322, MoSe₂ 1324, and WSe₂ 1326 grown by lateral conversion for varying amounts of lateral growth.

The steps of the process are shown schematically in FIG. 13A. Here, a tungsten oxide film as the reactive layer is used, sandwiched between two non-reactive layers of silicon oxide. All layers were deposited using Atomic Layer Deposition (ALD) without breaking the vacuum, which ensured high quality interfaces and allowed reactive layer thickness control with angstrom precision. The films were then etched using standard lithography to expose the desired edges and reacted to produce the final TMD pattern. An optical microscopy image in FIG. 13B shows the conversion at different growth times, demonstrating the ability to convert within arbitrarily defined patterns and the conversion progress vs. time. The transmission electron microscopy (TEM) image and corresponding plot in FIG. 13C, show that the number of TMD layers can be controlled by varying the thickness of the precursor oxide. It has been shown that reproducibly synthesized patterned layers of WS₂, WSe₂, MoS₂, and MoSe₂ material (FIG. 13D) can be created. It is thought that this can be extended to other transition metals and chalcogens, as well as to creating alloys by depositing mixed oxidizer converting with mixed chalcogen sources.

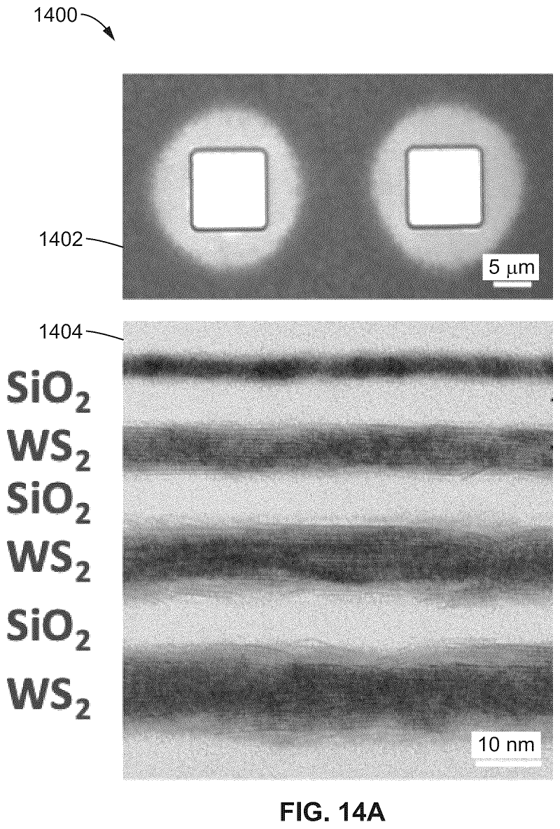

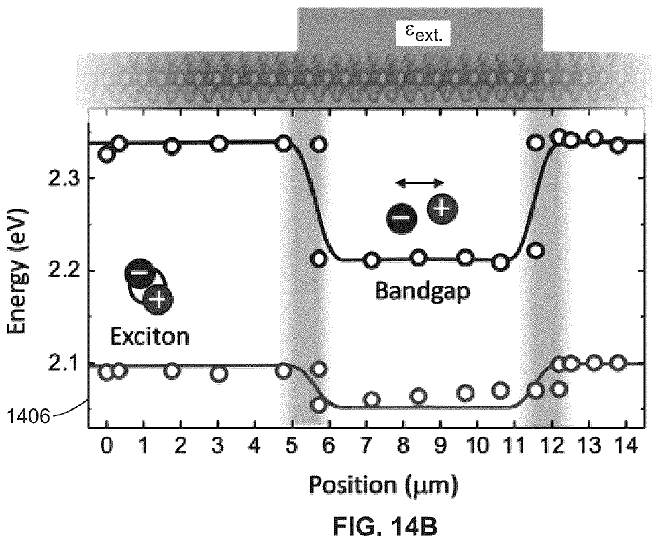

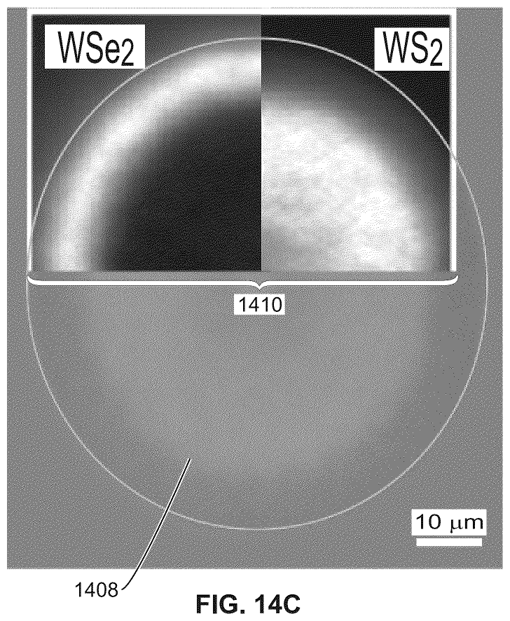

Refer now to FIG. 14A through FIG. 14C. FIG. 14A is an optical microscope image 1400, and corresponding cross-sectional high-resolution transmission electron microscopy (HRTEM) image of a WS₂/SiO₂ multilayer structure 1402. FIG. 14B is a schematic diagram 1404 of the effect of a patterned transition metal dichalcogenide (TMD) interface on its band structure. FIG. 14C is an optical microscope image 1406 overlaid with scanning confocal Raman spectroscopy indicating the composition.

The ability to make multilayer structures and lateral heterostructures is also quite desirable for advanced device architectures. The ability to make multilayer structures by alternating layers of SiO₂ and WOₓ during deposition has been demonstrated. FIG. 14A shows an optical image (top), and a cross-sectional TEM image (bottom), of a multilayer structure consisting of alternating layers of SiO₂ and WS₂. It should be possible to produce alternating layers of different TMDs by alternating the metal oxide precursor. Further tuning of the TMD properties, either of single embedded layers, or of multiple layer stacks, should be possible by changing the dielectric used. It has been shown that the band levels of TMDs are highly dependent on the dielectric environment (FIG. 14B). The ability to form lateral heterostructures by switching the chalcogen precursor during the lateral conversion process has also been shown. FIG. 14C shows an optical microscope image of a WSe₂/WS₂ lateral heterostructure, overlaid with a scanning confocal Raman intensity map, identifying the chemical composition.

While there are many exciting possibilities using the above method, the two most important areas for improvement are crystal domain size (for improved electrical and optical properties) and lower synthesis temperatures (for back-end CMOS integration). However, these are conflicting requirements, since lower temperature results in lower crystal quality. A common method for increasing domain size independent of temperature is to employ graphoepitaxial substrates, such as sapphire. It is therefore envisioned that adding layers such as large-area exfoliated graphene or boron nitride between the precursor layers before conversion is possible. Other promising domain size enhancement methods include the use of chemical catalysts or surfactants, growth of 2D TMDs on gold/tungsten foils using CVD, using Co and Ni enhance the post growth recrystallization of annealed WS₂ films encapsulated by SiO₂, and using alkali metal halides to suppress nucleation during CVD growth. To lower the conversion temperature even further, alternative chalcogen sources with lower cracking temperatures could be used, such as dimethyl disulfide and dimethyl diselenide.

Dimensional scaling of the patterned reactive layer may provide another interesting opportunity. By scaling the lateral dimension down to the 10-20 nm range, it may be possible to reach near single-crystal quality and have a more uniform chemical conversion. The shorter diffusion length may also provide opportunities to lower the conversion temperature. Initial scaling down to 50-100 nm can be tested by e-beam lithography followed by reactive ion etching, while scaling down to 10 nm feature sizes can be done by directed self-assembly of block copolymers followed by reactive ion etching. These patterns could be guided by co-design and be readily patternable to form gated devices with internal active elements in a pixel scaled down into the sub-wavelength regime.

In parallel to optimizing growth conditions for low temperature, methods for transferring as-grown lithographically patterned structures will be developed, borrowing from established methods. The lateral conversion method enables the synthesis of complex heterostructures at lithographically defined locations precisely matched to the target. Because this is a wafer scalable process, the patterned TMD elements could potentially be transferred in one operation using wafer-to-wafer alignment to the CMOS wafer (similar to 3D wafer integration). Furthermore, since the TMDs will be semi-encapsulated, they have a built-in protective surface layer that can preserve integrity during the transfer process, potentially enabling incorporation of air sensitive TMDs.

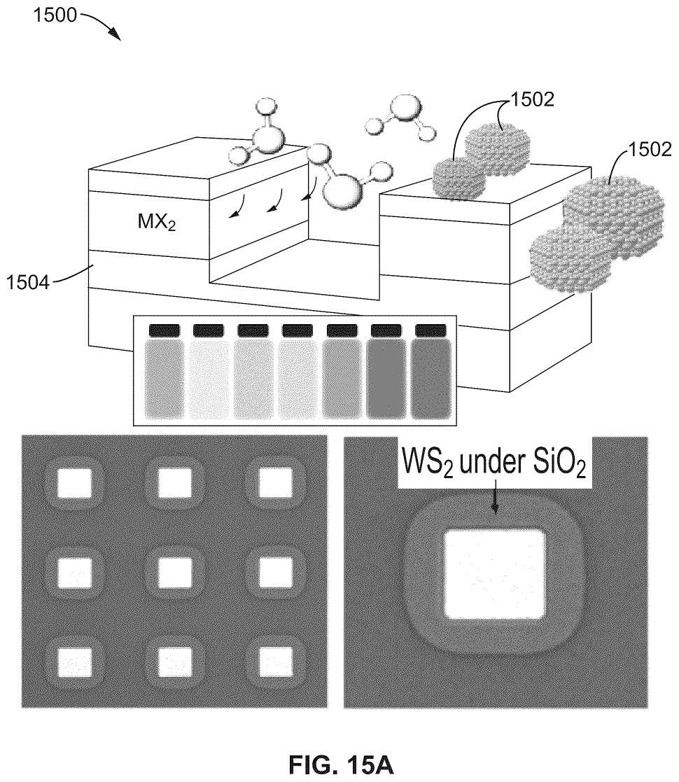

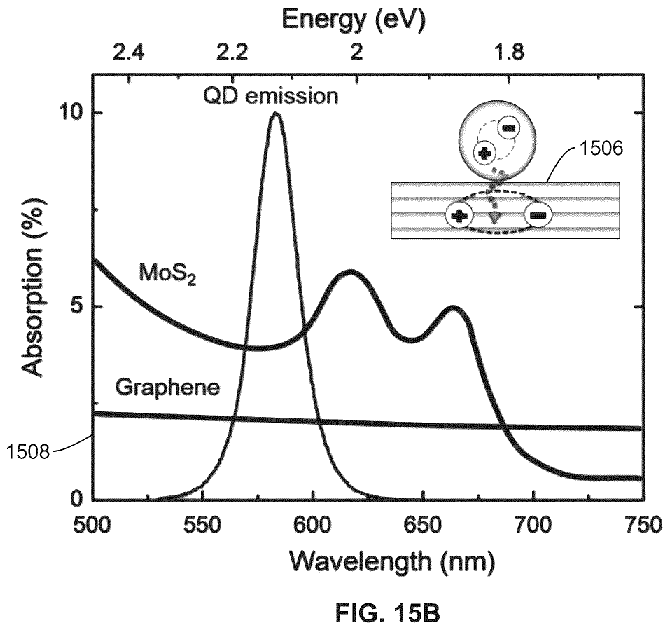

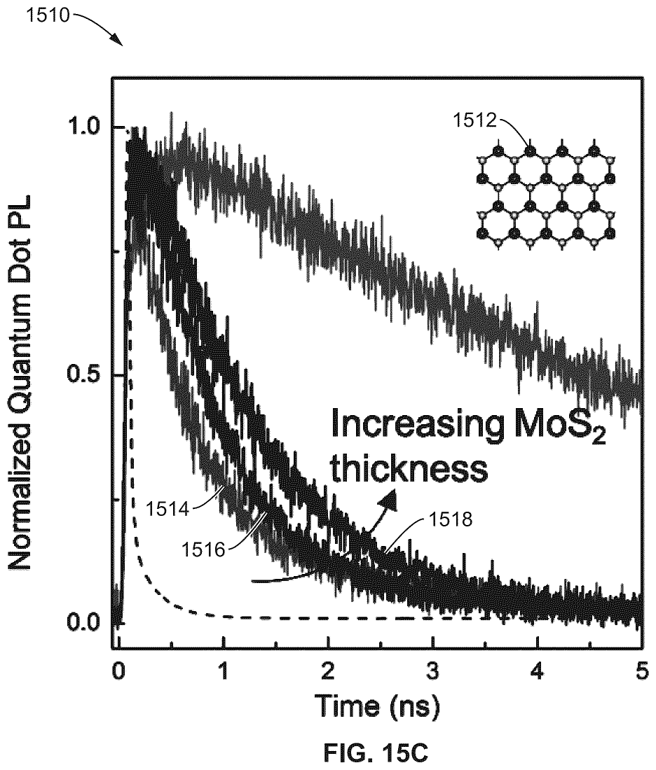

Refer now to FIG. 15A through FIG. 15C. FIG. 15A is a depiction 1500 of quantum dots 1502 functionalizing encapsulated TMD 1504 surface and exposed edges. Examples of energy transfer from quantum dot to 2D materials. FIG. 15B shows 1506 a monolayer MoS₂ and graphene device where a graph of absorption 1508 is overlaid with visible quantum dot emission. FIG. 15C is a graph 1510 of the decay rate of quantum dots 1512 enhanced by an order of magnitude due to energy transfer on MoS₂ (curves 1514, 1516, and 1518) compared to that on insulating SiO₂. Monolayer MoS₂ 1514 shows the highest rates of energy transfer compared to thicker layers 1516 and 1518.

Laterally converted TMD samples offer edge and surface state access for functionalization, which is important for photodetector design. In particular, the top surface oxide can be tuned to be very thin using ALD, or fully exposed post-fabrication for attaching dyes or quantum dots, which will enable energy or charge transfer (FIG. 15A). Section 3.1 discussed how energy from detected photons is transferred to a shelving state via energy transfer before amplification for readout. The energy transfer rate from quantum dots to 2D TMDs is well studied and can be tuned by the choice of quantum dot, the TMD size/thickness, and the spacer layer between them. Previous works have demonstrated that the rates of energy transfer are highest with thinner acceptor TMD layers due to reduced dielectric screening. Here, ultrafast optical spectroscopy will be used to measure time-resolved photoluminescence and quantify energy transfer and the total rate of recombination in functionalized TMD and CNT devices. The results will in turn be used as inputs to the co-design framework. The same spectroscopy set-ups can be used to obtain luminescence maps and exciton diffusion across the device structure, as well as to understand device homogeneity and underlying photo-physics. After studying prototypical samples, DNA self-assembly methods described in Section 3.7 will be used to impart homogeneous attachment of quantum dots across an array of lithographically patterned TMD devices.

### 3.7 Self-Assembly of Separately Synthesized Devices

The placement of synthesized CNTs as shown in FIG. 7 can be done for single pixels as discussed in Section 3.5. However, for a practical imager, a regular array is needed with precise placement in many pixels at once. Integrating lithographic fabrication with placement of individual devices in a scalable, high yield fabrication process with thousands or even millions of such devices is a huge unsolved challenge. In this case the problem is complicated by having two very different patterning scales: multiple devices within a pixel must be placed 10-100 nm apart (within one wavelength of light), while the whole pixel must be stepped and repeated with a period of order 10μ. A possible solution to be investigated is a hybrid approach where (i) the devices within a single pixel are self-assembled without the use of lithography, and (ii) these self-assembled pixel patterns are self-aligned onto lithographically defined locations on CMOS device. One can think of (i) as snowflakes, which form into a regular shape without any help (except that the shape is defined), and (ii) as a specially prepared surface such that snowflakes landing on it settle only into predefined locations. Both steps will leverage advances in DNA nanotechnology made over the past decade.

For the single pixel pattern, we use the recently developed DNA array “origami” technology as a nanoscale breadboard onto which nano-devices self-align. A micron-scale DNA array can present up to 8,704 binding sites, spaced by 6 nm, each with a unique DNA sequence. These nano-breadboards can be rapidly produced with automated protocols.

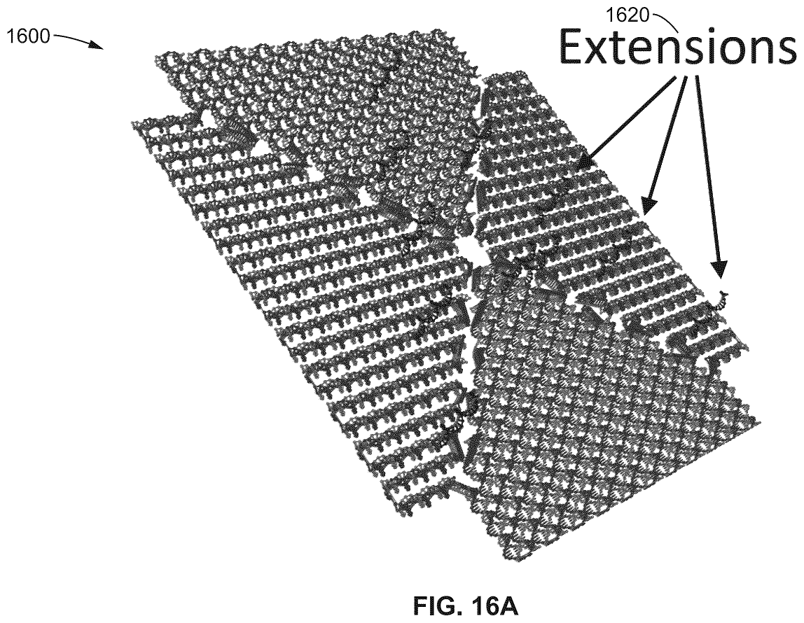

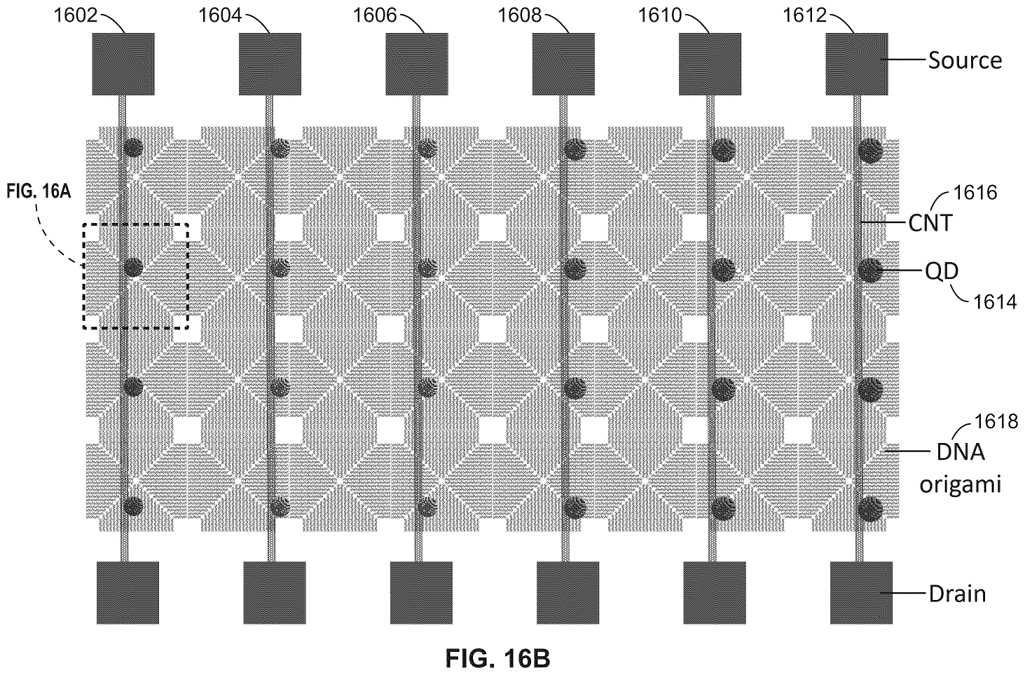

Refer now to FIG. 16, which is a depiction 1600 of a possible single pixel layout with six CNT channels 1602, 1604, 1606, 1608, 1610, 1612 functionalized with quantum dots 1614 that can be tuned to different wavelengths of light. The CNTs 1616 are self-aligned on a DNA origami array 1618 via complementary DNA pairing. The extensions 1620 enable alignment to lithographically defined patterns.

FIG. 16 shows a possible configuration with commercially available, semiconducting CNT transistors and semiconductor nanocrystal quantum dots (QDs) as photon absorbers to transfer exactions to CNTs. Similar CNT placement has been previously achieved. QDs are of interest for this project because they allow tuning each to respond to a different wavelength of light, and a way to synthesize DNA-functionalized QDs with a tunable bandgap has already been developed. Billions of copies of this single pattern can be self-assembled in solution.

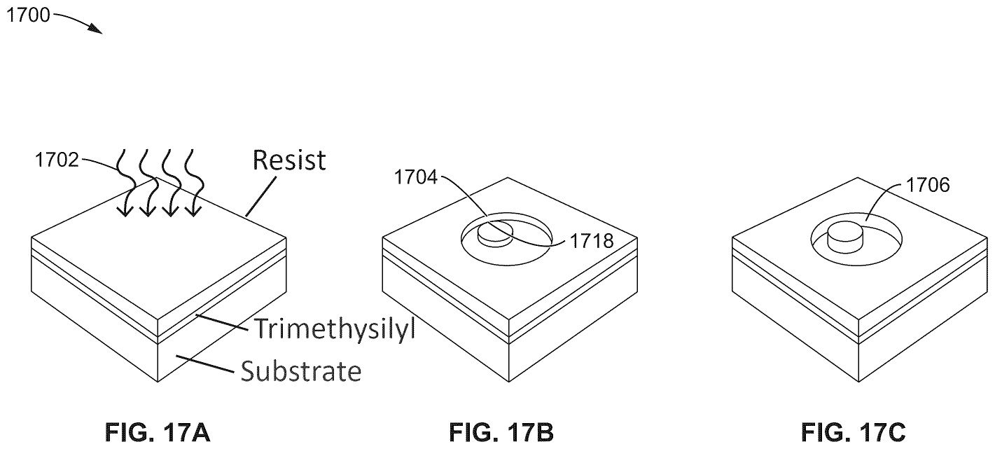

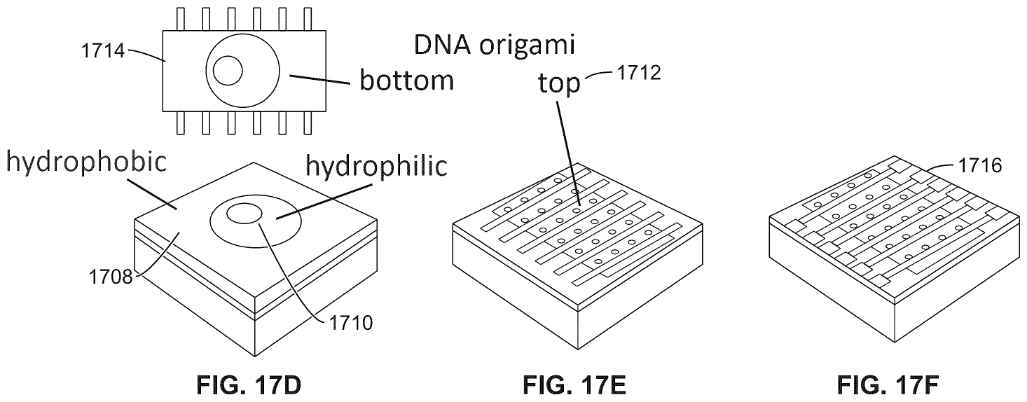

Refer now to FIG. 17A through FIG. 17E, which show 1700 a method of self-alignment of nanosensors onto a lithographically patterned CMOS device. FIG. 17A shows the initial photolithography 1702 of an asymmetric patch. FIG. 17B shows a plasma etch 1704. FIG. 17C shows photoresist stripping 1706, resulting in FIG. 17D a hydrophobic 1708 and hydrophilic 1710 region. FIG. 17E shows the top 1712 and bottom 1714 DNA array alignment. FIG. 17F shows metal contact deposition 1716. The offset circle 1718 (shown in various stages in FIG. 17B, FIG. 17C, and FIG. 17D) is one of the shapes that allows thermodynamically-controlled self-alignment with no kinetic trap states. Only one pixel is shown, but millions of devices can be simultaneously self-aligned.

The self-assembled single pixel patterns above must now be placed on pre-defined locations at wafer scale. To do this, FIG. 17A through FIG. 17E illustrate such for a single location (there would be a large matrix of such locations). First, an array of round shapes (patches) will be created with asymmetrically placed circles by photolithographic patterning of a silicon substrate coated with a hydrophobic layer such as trimethysilyl (FIG. 17A). The patches will then be made hydrophilic by etching with oxygen plasma (FIG. 17B) and stripping the resist (FIG. 17C). Next, the above solution can be added containing the DNA array patterns, which will have an extension pattern on the bottom matching the asymmetrically-placed circles. This bottom pattern allows them to self-align with the hydrophilic patches (FIG. 17D). After the alignment, achieved by a one-hour incubation of the solution on the wafer, the excess solution will be removed and metal contacts lithographically deposited to electrically connect CNTs to the CMOS chip pads as in FIG. 2 (Section 3.4). After metal deposition, the remaining DNA can be rinsed out to leave CNTs with electronic properties unaltered by DNA binding. Such a process would not damage the CMOS chip, as it can be performed at room temperature and does not use corrosive chemicals.

A significant difference between the disclosed approach and that of other available art is that here, 64 times larger, micron-scale DNA arrays are used. Such larger arrays should enable highly scalable and accessible optical wafer patterning rather than slow, serial E-beam lithography. In addition, these arrays have about 9000 uniquely addressable binding sites, enabling assembly of many different DNA-functionalized components such as CNTs and quantum dots simultaneously. It is noted that image sensors are a particularly suitable application for self-assembly, because thousands of identical components need to be organized into a periodic lattice.

In some embodiments, a device comprises a pixelated electronic sensor. In some embodiments, the device includes a CMOS sensor and a plurality of receptors. Multiple receptors are positioned within each pixel of the CMOS sensor. In some embodiments, each receptor is a nano-material. Nano-material can be positioned distances that are less than one wavelength (e.g., infrared wavelengths to ultraviolet wavelengths) apart from one another.

In some embodiments, the nano-materials comprise functionalized carbon nanotubes.

In some embodiments, the functionalized carbon nanotubes are functionalized with molecules (e.g., C₆₀ or Poly(3-hexylthiophene-2,5-diyl) (P3HT)) and/or with nanodots (e.g., tungsten disulfide (WS₂) nanodots). In some embodiments, each of the functionalized carbon nanotubes associated with a single pixel is operable to absorb a different wavelength of light.

In some embodiments, the nano-materials comprise transition metal dichalcogenides (TMDs).

In some embodiments, with multiple receptors positioned with each pixel of the CMOS sensor, no photons are wasted. Each photo is absorbed by one of the receptors, depending on the wavelength (i.e., color) of the photon.

In some embodiments, the receptors are integrated with the CMOS integrated circuit using low temperature post-processing (e.g., self-assembly of receptors on the surface of the CMOS sensor).

In some embodiments, a process for making a device includes the following operations:
(a) Provide an integrated circuit;
(b) Planarize the integrated circuit;
(c) Deposit a receptor gate dielectric (e.g., silicon nitride, sapphire, hexagonal boron nitride) on a gate electrode;
(d) Deposit receptors (e.g., using a DNA-based self-assembly or by patterning and lateral conversion for low temperature TMDs);
(e) Deposit and lithographically pattern interconnects (e.g., palladium interconnects) from receptors to integrated circuit electrodes; and
(f) Deposit functionalizing molecules or nanodots on the receptors (e.g., using lithographic patterning or by DNA-based self-assembly, depending on the material).

In some embodiments, the device can be used for imaging from infrared wavelengths to ultraviolet wavelengths. In some embodiments, each pixel of the device has color-resolved single photon sensitivity without dark counts and without inefficiency. In some embodiments, the device operates at temperatures above about 70 Kelvin.

From the description herein, it will be appreciated that the present disclosure encompasses multiple implementations of the technology which include, but are not limited to, the following:

An apparatus or method or system, comprising: (a) a CMOS sensor and a plurality of receptors; (b) wherein multiple receptors are positioned within each pixel of the CMOS sensor.

The apparatus or method or system of any preceding or subsequent implementation, wherein each receptor is a nano-material.

The apparatus or method or system of any preceding or subsequent implementation, wherein each nano-material is positioned within one wavelength from another nano-material.

The apparatus or method or system of any preceding or subsequent implementation, wherein the wavelength corresponds to a range from infrared to ultraviolet light.

The apparatus or method or system of any preceding or subsequent implementation, wherein the nano-material comprises functionalized carbon nanotubes (CNTs).

The apparatus or method or system of any preceding or subsequent implementation, wherein the functionalized carbon nanotubes are functionalized with molecules selected from a group consisting of: C₆₀, Poly(3-hexylthiophene-2,5-diyl) (P3HT)), and nanodots.

The apparatus or method or system of any preceding or subsequent implementation, wherein the nanodots substantially comprise tungsten disulfide (WS₂).

The apparatus or method or system of any preceding or subsequent implementation, wherein each of the functionalized carbon nanotubes associated within a single pixel is operable to absorb a different wavelength of light.

The apparatus or method or system of any preceding or subsequent implementation, wherein the nano-material comprises transition metal dichalcogenides (TMDs).

The apparatus or method or system of any preceding or subsequent implementation, wherein, among the multiple receptors positioned within each pixel of the CMOS sensor, no photons are wasted.

The apparatus or method or system of any preceding or subsequent implementation, wherein each incident photon within the wavelength is absorbed by one of the receptors within the pixel.

The apparatus or method or system of any preceding or subsequent implementation, wherein the receptors are integrated with the CMOS integrated circuit by the use of low temperature post-processing.

The apparatus or method or system of any preceding or subsequent implementation, wherein low temperature comprises a temperature below that which would be required to chemically change either the CMOS sensor, receptor, or the spatial relationship between the CMOS sensor and the receptor.

An apparatus or method or system for assembling a pixel within an electronic imaging sensor, comprising: (a) providing an integrated circuit on a wafer; (b) planarizing the integrated circuit on the wafer; and (c) depositing a receptor gate dielectric on the integrated circuit.

The apparatus or method or system of any preceding or subsequent implementation, wherein the receptor gate dielectric is selected from a group of dielectrics comprising: silicon nitride, sapphire, hexagonal boron nitride.

The apparatus or method or system of any preceding or subsequent implementation, further comprising depositing one or more receptors over the receptor gate.

The apparatus or method or system of any preceding or subsequent implementation, wherein the depositing step comprises either a DNA-based self-assembly or a patterning and lateral conversion for a low temperature patterned transition metal dichalcogenide (TMD).

The apparatus or method or system of any preceding or subsequent implementation, further comprising depositing and lithographically forming one or more interconnects between the receptors to the integrated circuit electrodes.

The apparatus or method or system of any preceding or subsequent implementation, wherein the interconnects substantially comprise palladium.

The apparatus or method or system of any preceding or subsequent implementation, further comprising depositing one or more functionalizing molecules or nanodots on the receptors.

The apparatus or method or system of any preceding or subsequent implementation, further comprising sensing incident photons having wavelengths in a sensing range from infrared to ultraviolet.

The apparatus or method or system of any preceding or subsequent implementation, wherein each pixel has color-resolved single photon sensitivity without dark counts.

The apparatus or method or system of any preceding or subsequent implementation, wherein each incident photon within the sensing range is sensed with 100% efficiency.

The apparatus or method or system of any preceding or subsequent implementation, wherein the device operates at temperatures above about 70° Kelvin.

As used herein, term “implementation” is intended to include, without limitation, embodiments, examples, or other forms of practicing the technology described herein.

As used herein, the singular terms “a,” “an,” and “the” may include plural referents unless the context clearly dictates otherwise. Reference to an object in the singular is not intended to mean “one and only one” unless explicitly so stated, but rather “one or more.”

Phrasing constructs, such as “A, B and/or C”, within the present disclosure describe where either A, B, or C can be present, or any combination of items A, B and C. Phrasing constructs indicating, such as “at least one of” followed by listing a group of elements, indicates that at least one of these group elements is present, which includes any possible combination of the listed elements as applicable.

References in this disclosure referring to “an embodiment”, “at least one embodiment” or similar embodiment wording indicates that a particular feature, structure, or characteristic described in connection with a described embodiment is included in at least one embodiment of the present disclosure. Thus, these various embodiment phrases are not necessarily all referring to the same embodiment, or to a specific embodiment which differs from all the other embodiments being described. The embodiment phrasing should be construed to mean that the particular features, structures, or characteristics of a given embodiment may be combined in any suitable manner in one or more embodiments of the disclosed apparatus, system or method.

As used herein, the term “set” refers to a collection of one or more objects. Thus, for example, a set of objects can include a single object or multiple objects.

Relational terms such as first and second, top and bottom, upper and lower, left and right, and the like may be used solely to distinguish one entity or action from another entity or action without necessarily requiring or implying any actual such relationship or order between such entities or actions.

The terms “comprises,” “comprising,” “has”, “having,” “includes”, “including,” “contains”, “containing” or any other variation thereof, are intended to cover a non-exclusive inclusion, such that a process, method, article, or apparatus that comprises, has, includes, contains a list of elements does not include only those elements but may include other elements not expressly listed or inherent to such process, method, article, or apparatus. An element proceeded by “comprises . . . a”, “has . . . a”, “includes . . . a”, “contains . . . a” does not, without more constraints, preclude the existence of additional identical elements in the process, method, article, or apparatus that comprises, has, includes, contains the element.

As used herein, the terms “approximately”, “approximate”, “substantially”, “essentially”, and “about”, or any other version thereof, are used to describe and account for small variations. When used in conjunction with an event or circumstance, the terms can refer to instances in which the event or circumstance occurs precisely as well as instances in which the event or circumstance occurs to a close approximation. When used in conjunction with a numerical value, the terms can refer to a range of variation of less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, “substantially” aligned can refer to a range of angular variation of less than or equal to ±10°, such as less than or equal to ±5°, less than or equal to ±4°, less than or equal to ±3°, less than or equal to ±2°, less than or equal to ±1°, less than or equal to ±0.5°, less than or equal to ±0.1°, or less than or equal to ±0.05°.

Additionally, amounts, ratios, and other numerical values may sometimes be presented herein in a range format. It is to be understood that such range format is used for convenience and brevity and should be understood flexibly to include numerical values explicitly specified as limits of a range, but also to include all individual numerical values or sub-ranges encompassed within that range as if each numerical value and sub-range is explicitly specified. For example, a ratio in the range of about 1 to about 200 should be understood to include the explicitly recited limits of about 1 and about 200, but also to include individual ratios such as about 2, about 3, and about 4, and sub-ranges such as about 10 to about 50, about 20 to about 100, and so forth.

The term “coupled” as used herein is defined as connected, although not necessarily directly and not necessarily mechanically. A device or structure that is “configured” in a certain way is configured in at least that way, but may also be configured in ways that are not listed.

Benefits, advantages, solutions to problems, and any element(s) that may cause any benefit, advantage, or solution to occur or become more pronounced are not to be construed as a critical, required, or essential features or elements of the technology describes herein or any or all the claims.

In addition, in the foregoing disclosure various features may be grouped together in various embodiments for the purpose of streamlining the disclosure. This method of disclosure is not to be interpreted as reflecting an intention that the claimed embodiments require more features than are expressly recited in each claim. Inventive subject matter can lie in less than all features of a single disclosed embodiment.

The abstract of the disclosure is provided to allow the reader to quickly ascertain the nature of the technical disclosure. It is submitted with the understanding that it will not be used to interpret or limit the scope or meaning of the claims.

It will be appreciated that the practice of some jurisdictions may require deletion of one or more portions of the disclosure after that application is filed. Accordingly, the reader should consult the application as filed for the original content of the disclosure. Any deletion of content of the disclosure should not be construed as a disclaimer, forfeiture or dedication to the public of any subject matter of the application as originally filed.

The following claims are hereby incorporated into the disclosure, with each claim standing on its own as a separately claimed subject matter.

Although the description herein contains many details, these should not be construed as limiting the scope of the disclosure but as merely providing illustrations of some of the presently preferred embodiments. Therefore, it will be appreciated that the scope of the disclosure fully encompasses other embodiments which may become obvious to those skilled in the art.

All structural and functional equivalents to the elements of the disclosed embodiments that are known to those of ordinary skill in the art are expressly incorporated herein by reference and are intended to be encompassed by the present claims. Furthermore, no element, component, or method step in the present disclosure is intended to be dedicated to the public regardless of whether the element, component, or method step is explicitly recited in the claims. No claim element herein is to be construed as a “means plus function” element unless the element is expressly recited using the phrase “means for”. No claim element herein is to be construed as a “step plus function” element unless the element is expressly recited using the phrase “step for”.

What is claimed is:

1. A pixelated electronic sensor, comprising:
(a) a CMOS sensor and a plurality of receptors;
(b) wherein multiple receptors are positioned within each pixel of the CMOS sensor.

2. The sensor of claim 1, wherein each receptor is a nano-material.

3. The sensor of claim 2, wherein each nano-material is positioned within one wavelength from another nano-material.

4. The sensor of claim 3, wherein the wavelength corresponds to a range from infrared to ultraviolet light.

5. The sensor of claim 2, wherein the nano-material comprises functionalized carbon nanotubes (CNTs).

6. The sensor of claim 5, wherein the functionalized carbon nanotubes are functionalized with molecules selected from a group consisting of: C₆₀, Poly(3-hexylthiophene-2,5-diyl) (P3HT)), and nanodots.

7. The sensor of claim 6, wherein the nanodots substantially comprise tungsten disulfide (WS₂).

8. The sensor of claim 5, wherein each of the functionalized carbon nanotubes associated within a single pixel is operable to absorb a different wavelength of light.

9. The sensor of claim 2, wherein the nano-material comprises transition metal dichalcogenides (TMDs).

10. The sensor of claim 1, wherein, among the multiple receptors positioned within each pixel of the CMOS sensor, no photons are wasted.

11. The sensor of claim 4, wherein each incident photon within the wavelength is absorbed by one of the receptors within the pixel.

12. The sensor of claim 1, wherein the receptors are integrated with the CMOS integrated circuit by the use of low temperature post-processing.

13. The sensor of claim 12, wherein low temperature comprises a temperature below that which would be required to chemically change either the CMOS sensor, receptor, or the spatial relationship between the CMOS sensor and the receptor.

14. A method for assembling a pixel within an electronic imaging sensor, comprising:
(a) providing an integrated circuit on a wafer;
(b) planarizing the integrated circuit on the wafer; and
(c) depositing a receptor gate dielectric on the integrated circuit.

15. The method of claim 14, wherein the receptor gate dielectric is selected from a group of dielectrics comprising: silicon nitride, sapphire, hexagonal boron nitride.

16. The method of claim 15, further comprising depositing one or more receptors over the receptor gate.

17. The method of claim 16, wherein the depositing step comprises either a DNA-based self-assembly or a patterning and lateral conversion for a low temperature patterned transition metal dichalcogenide (TMD).

18. The method of claim 17, further comprising depositing and lithographically forming one or more interconnects between the receptors to the integrated circuit electrodes.

19. The method of claim 18, wherein the interconnects substantially comprise palladium.

20. The method of claim 19, further comprising depositing one or more functionalizing molecules or nanodots on the receptors.
